(19) United States
(12) Patent Application Publication
(10) Pub. No.: US 2026/0206263 A1
(43) Pub. Date: Jul. 16, 2026

(54) SEMICONDUCTOR STRUCTURE HAVING BRIDGING EPITAXY FEATURE AND METHOD FOR MANUFACTURING THE SAME

(71) Applicant: TAIWAN SEMICONDUCTOR MANUFACTURING COMPANY, LTD., Hsinchu (TW)

(72) Inventors: Zhi-Ren XIAO, Hsinchu (TW); Nuo XU, Hsinchu (TW); Chia-Wen LIU, Hsinchu (TW); Chun-Fu CHENG, Hsinchu (TW); Chih-Ching WANG, Hsinchu (TW); Sean MA, Hsinchu (TW); Chung-Wei WU, Hsinchu (TW); Zhiqiang WU, Hsinchu (TW)

(73) Assignee: TAIWAN SEMICONDUCTOR MANUFACTURING COMPANY, LTD., Hsinchu (TW)

(21) Appl. No.: 19/024,187

(22) Filed: Jan. 16, 2025

(51) Int. Cl. H10D 62/00; H01L 21/02; H10D 30/00; H10D 30/01; H10D 62/13; H10D 64/23

(52) U.S. Cl. CPC H10D 62/01; H10D 30/0195; H10D 30/508; H10D 62/151; H10P 14/20; H10P 14/3211; H10D 64/258

(57) ABSTRACT

A method for manufacturing a semiconductor structure includes: forming a patterned structure on a substrate, the patterned structure including: two first channel features spaced apart from each other by a source/drain recess; two second channel features disposed respectively beneath the two first channel features; two first sacrificial features disposed between the two first channel features and the two second channel features; two second sacrificial features disposed beneath the two second channel features; two first inner spacers that separate the two first sacrificial features from the source/drain recess, respectively; and two second inner spacers that separate the two second sacrificial features from the source/drain recess, respectively; forming a bridging epitaxial feature which interconnects two predetermined inner spacers that are the two first inner spacers or the two second inner spacers; and forming a vertically grown epitaxial feature from the bridging epitaxial feature in a vertical direction normal to the substrate.

### BACKGROUND

Moore's Law, which predicts the doubling of transistor density on integrated circuits every two years, faces increasing challenges in the continued scaling of CMOS devices. As size of devices shrink, phenomena such as short-channel effects (SCEs) become more pronounced, leading to performance degradation and power inefficiency. Short-channel effects occur when the transistor's channel length becomes comparable to the depletion regions of the source and drain, causing unintended leakage currents and reduced control over the channel. Additionally, fringing capacitance, which arises from the parasitic capacitance between different layers of the device, also increases with scaling, further affecting switching speed and power consumption, causing difficulty to maintain the pace of Moore's Law. Therefore, the development of new materials, architectures, and techniques are necessary to continue advancement of semiconductor technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 33 are schematic views illustrating intermediate stages of the method for manufacturing the semiconductor structure in accordance with some embodiments.

FIGS. 34 to 37 illustrate profiles of source/drain portions of the semiconductor structures in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

Source/drain portion(s) may refer to a source or a drain, individually or collectively dependent upon the context.

The present disclosure is directed to a semiconductor structure having a bridging epitaxial feature in a source/drain portion of the semiconductor structure, and a method for manufacturing the same. The semiconductor structure may have a p-type conductivity, and includes two first channel features, two second channel features, two active gates, two first inner spacers, two second inner spacers, and the source/drain portion. The two first channel features are spaced apart from each other by the source/drain portion. The two second channel features are disposed respectively beneath the two first channel features, and are spaced apart from each other by the source/drain portion. Each of the active gates is disposed to surround one of the two first channel features and a respective one of the two second channel features. Each of the two first inner spacers is disposed between the two first channel features and the respective one of the two second channel features to separate a respective one of the two active gates. Each of the two second inner spacers is disposed beneath one of the two second channel features to separate a respective one of the two active gates from the source/drain portion. Specifically, the source/drain portion includes the bridging epitaxial feature, and a vertically grown epitaxial feature. The bridging epitaxial feature interconnects two predetermined inner spacers, which may be the two first inner spacers, or the two second inner spacers. The vertically grown epitaxial feature is formed on the bridging epitaxial feature, and has a germanium content greater than a germanium content of the bridging epitaxial feature. In the method for manufacturing the semiconductor structure according to the present disclosure, the bridging epitaxial feature is formed at the two predetermined inner spacers that are located at substantially the same level, so as to provide a growing base for the vertically grown epitaxial feature to grow from the bridging epitaxial feature in a vertical direction. Such vertically grown epitaxial feature may provide a highly compressive stress to the first and second channel features, thereby enhancing performance of the p-type semiconductor structure.

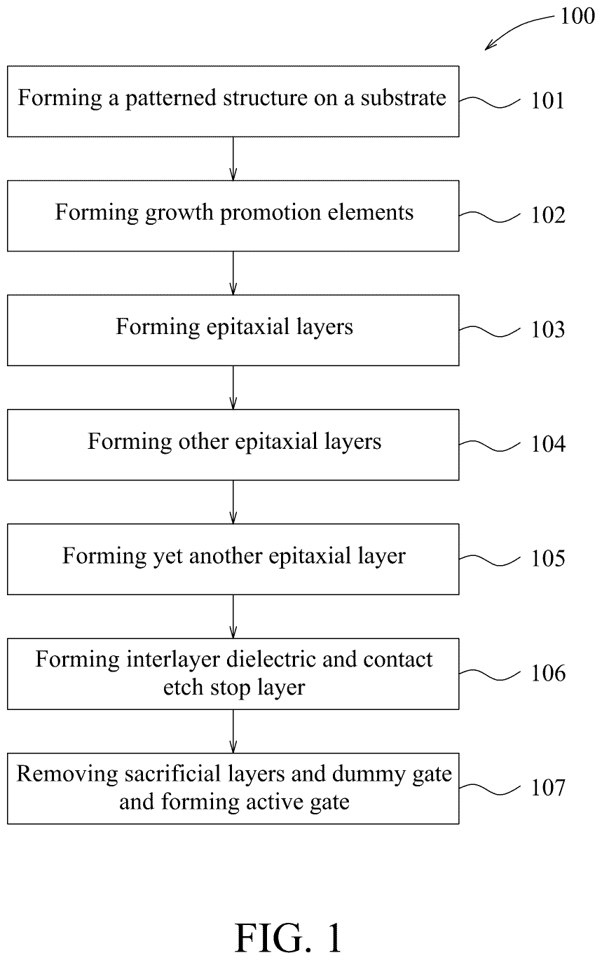

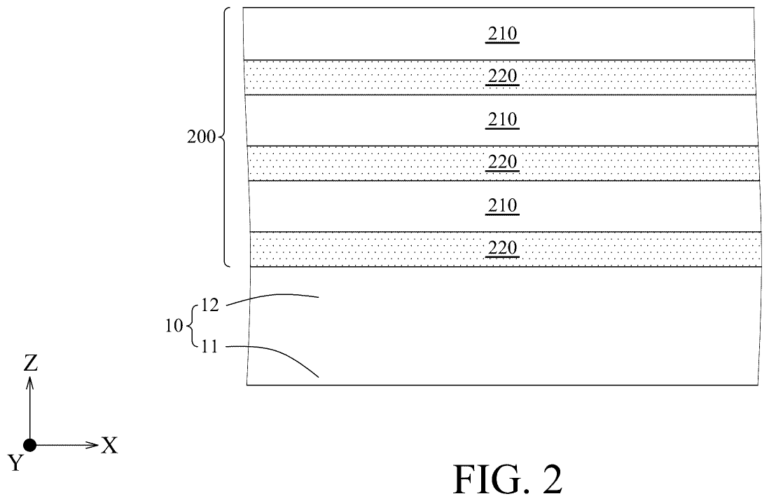

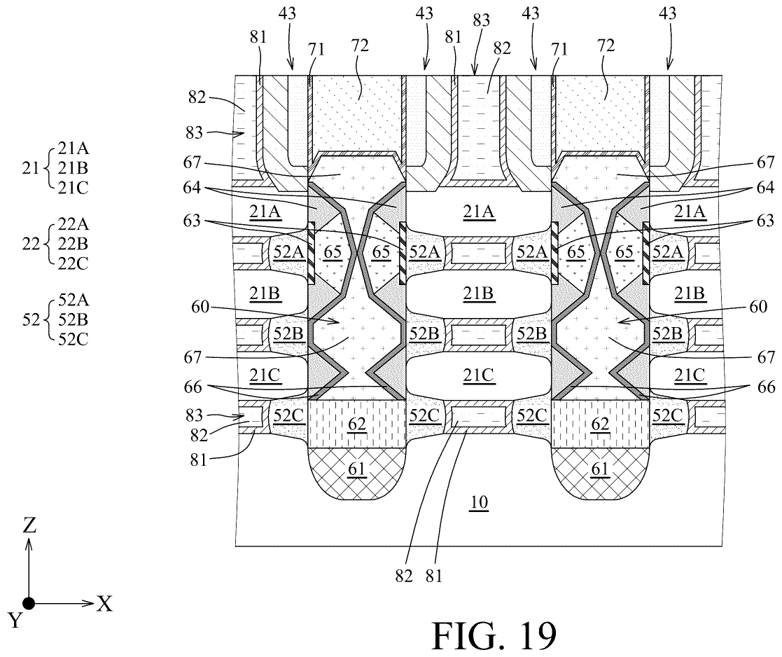

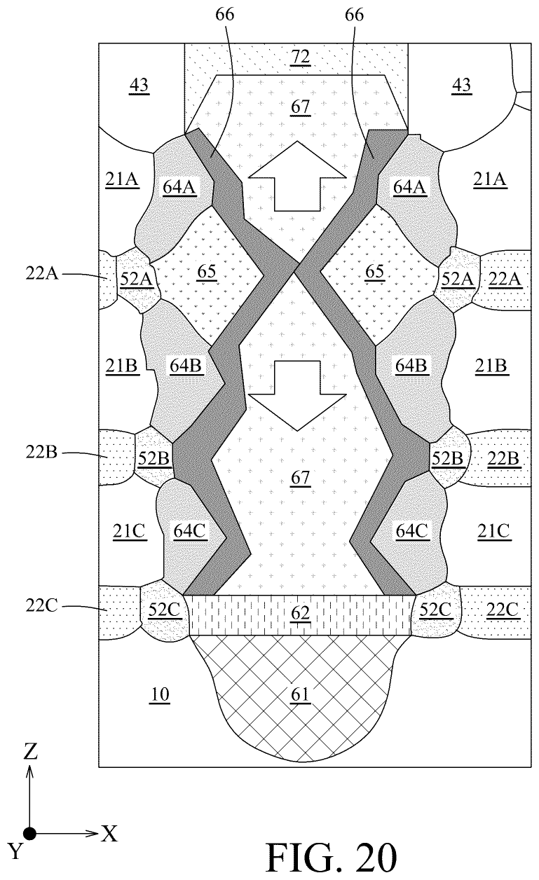

FIG. 1 is a flow diagram illustrating a method 100 for manufacturing the semiconductor structure (for example, the semiconductor structure shown in FIG. 19 or 20) in accordance with some embodiments. FIGS. 2 to 20 illustrate schematic views of intermediate stages of the method 100 in accordance with some embodiments. Some repeating structures are omitted in FIGS. 2 to 20 for the sake of brevity. Additional steps can be provided before, after or during the method 100, and some of the steps described herein may be replaced by other steps or be eliminated.

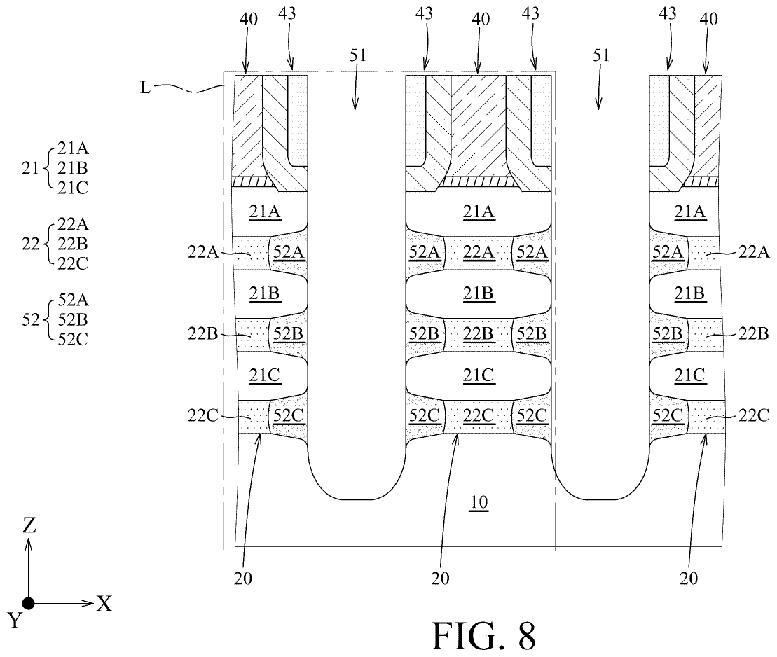

Referring to FIG. 1 and the examples illustrated in FIGS. 2 to 8, the method 100 begins at step 101, where a patterned structure (see FIG. 8) is formed on a substrate 10.

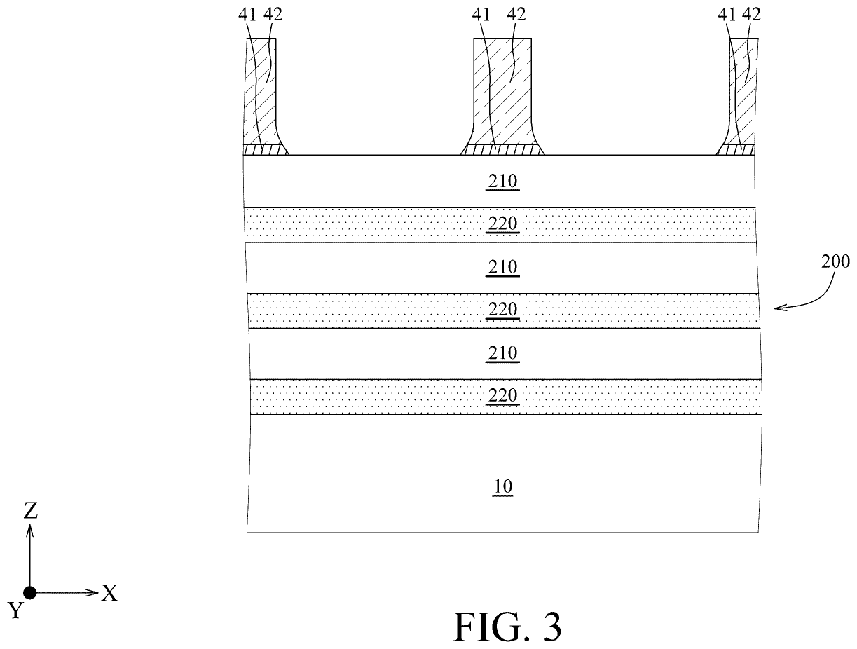

Referring to FIG. 2, step 101 may include forming nanosheet stacks 200 respectively on fins 12 of a substrate 10. FIG. 2 shows a cross-sectional view of a resultant structure taken along a longitudinal direction (X) (i.e., an X-cut) in accordance with some embodiments, in which one of the nanosheet stacks 200 and one of the fins 12 are shown. Please note that FIGS. 3 to 20 are respectively cross-sectional views similar to FIG. 2 to illustrate resultant structures of processes subsequent to that shown in FIG. 2.

In some embodiments, forming the nanosheet stacks 200 may include forming a nanosheet material stack (not shown) on a starting substrate (not shown); and performing a patterning process to form the nanosheet material stack into a plurality of the nanosheet stacks 200, and to form the starting substrate into the substrate 10 including a plurality of the fins 12 and a base 11. Other suitable processes for forming the nanosheet stacks 200 and the fins 12 are also within the contemplated scope of the present disclosure.

The starting substrate may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The starting substrate may be doped with p-type impurities or n-type impurities, or undoped. In addition, the starting substrate may be a bulk silicon substrate, a silicon-on-insulator (SOI) substrate, or a germanium-on-insulator (GOI) substrate. In some embodiments, the starting substrate may be made of silicon. Other suitable materials for forming the starting substrate are within the contemplated scope of the present disclosure.

The nanosheet material stack includes first nanosheet layers and second nanosheet layers that are alternatively stacked on each other over the starting substrate and that may be formed using any suitable deposition processes, such as physical vapor deposition (PVD), chemical vapor deposition (CVD), atomic layer deposition (ALD), or the likes, or combinations thereof, but are not limited thereto. In the following description, a deposition process, unless otherwise stated or defined in this disclosure, may be performed in a way similar to the above-mentioned ones. The first nanosheet layers will be formed into channel features 21 (see FIG. 8), while the second nanosheet layers are to be formed into sacrificial features 22 (see FIG. 8) which will be removed in subsequent steps. The first nanosheet layers are made of a first semiconductor material, and the second nanosheet layers are made of a second semiconductor material different from the first semiconductor material. Possible materials for the first and second semiconductor materials are similar to those for the starting substrate, and thus details thereof are omitted for the sake of brevity. In certain embodiments, the first nanosheet layers include silicon, while the second nanosheet layers include silicon germanium. In some embodiments, the nanosheet material stack may include three the first nanosheet layers, and three the second nanosheet layers, but are not limited thereto. Other suitable processes, materials and/or numbers for each of the first and second nanosheet layers are within the contemplated scope of the present disclosure.

The patterning process may include a photolithography process followed by an etching process. The photolithography process may include: forming a photoresist layer over a structure to be patterned by, for example, spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, unless otherwise stated or defined in this disclosure, may be performed in a way similar to the above-mentioned ones. After the patterning process, the nanosheet material stack is formed into the nanosheet stacks 200 that are spaced apart from each other in a transverse direction (Y) transverse to (e.g., perpendicular to) the longitudinal direction (X). The first nanosheet layers are formed into channel layers 210, and the second nanosheet layers are formed into sacrificial layers 220. The starting substrate is formed into the base 11, and the fins 12 that are spaced apart from each other in the transverse direction (Y) and that are disposed on the base 11. The nanosheet stacks 200 are respectively disposed on the fins 12 along a vertical direction (Z) transverse to (e.g., perpendicular to) the longitudinal direction (X) and the transverse direction (Y). The vertical direction (Z) is normal to the substrate 10. In some embodiments, masking layers (not shown) for patterning the nanosheet material stack into the nanosheet stacks 200 may remain on the nanosheet stacks 200, respectively.

In some embodiments, afterward, isolation elements (not shown) may be formed. Each of the isolation elements is formed on the base 11 between two adjacent ones of the fins 12. Such isolation elements may also be referred to as shallow trench isolations (STI). The isolation elements may be formed by: depositing an isolation material for forming the isolation elements using any suitable deposition processes over the structure shown in FIG. 2 such that the isolation material fills spaces among the nanosheet stacks 200; performing a planarization process (e.g., chemical mechanical polishing (CMP)) to obtain a planarized surface, through which the masking layers (not shown) remaining respectively on the nanosheet stacks 200 may be exposed; and etching back the isolation material using any suitable etching processes, such as dry etching, wet etching, anisotropic etching, or combinations thereof. In some embodiments, the isolation elements include a dielectric material, such as an oxide-based dielectric (e.g., silicon oxide), but is not limited thereto. Other suitable processes, materials and/or configurations of the isolation elements are within the contemplated scope of the present disclosure.

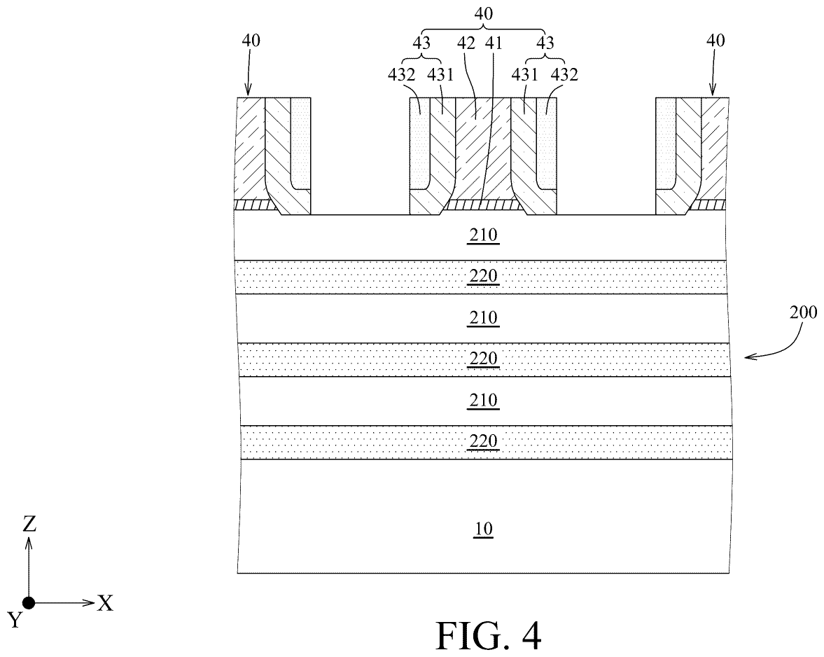

Referring to FIGS. 3 and 4, step 101 may further include forming gate structures 40 (see FIG. 4) over the nanosheet stacks 200 and the isolation elements (not shown). The gate structures 40 are spaced apart from each other in the longitudinal direction (X). Hereinafter, the nanosheet stacks 200 are described in singular form for easy understanding.

Forming the gate structures 40 may include forming dummy gates (see FIG. 3) on the nanosheet stack 200, each of the dummy gates including one of dummy dielectrics 41 and one of dummy electrodes 42; and forming pairs of gate spacer features 43 (see FIG. 4) that sandwich the dummy gates, respectively. Thereby, the gate structures 40, each including one of the dummy gates and a respective pair of the gate spacer features 43, are obtained.

The dummy gates may be formed by depositing first and second dummy layers (not shown) respectively for forming the dummy dielectrics 41 and the dummy electrodes 42 using any suitable deposition processes; performing a planarization process (e.g., CMP) to obtain a planar upper surface of the second dummy layer (i.e., a planarized second dummy layer); forming a third dummy layer (not shown) for forming a mask (not shown) on the planarized second dummy layer using any suitable deposition processes; and patterning the first dummy layer, the planarized second dummy layer and the third dummy layer to partially expose the fins 12 and the isolation elements using any suitable patterning processes and/or etching processes. The dummy dielectrics 41 may include a dielectric material, such as silicon oxide, or the likes. The dummy electrodes 42 may include polycrystalline silicon, or the likes. The mask may be a single layer structure, or a multi-layered structure. The mask may include a dielectric material, such as silicon nitride, silicon oxide, silicon oxynitride, or the likes, or combinations thereof. As shown in FIG. 3, in some embodiments, the dummy dielectric 41 and the dummy electrodes 42 may by formed with a footing shape. In other embodiments, the dummy dielectric 41 and the dummy electrodes 42 may by formed with a straight sidewall (not shown). Other suitable materials and/or processes and/or configuration for forming the dummy gates are within the contemplated scope of the present disclosure.

In some embodiments, each of the gate spacer features 43 has two gate spacers, namely, a first gate spacer 431 being formed on a corresponding one of the dummy gates, and a second spacer 432 being formed on the first gate spacer 431 opposite to the corresponding dummy gates. The first spacer 431 and the second spacer 432 may be made of different materials. Each of the first and second gate spacers 431, 432 may include a dielectric material, such as a silicon carbon-containing dielectric material, a silicon oxide-containing material, silicon nitride, other suitable materials, or combinations thereof. In other embodiments, there may be only one, or in some other embodiments, more than two of the gate spacers present in each of the gate spacer features 43. Exemplarily, the gate spacer features 43 are formed by sequentially depositing two spacer material layers for respectively forming the first gate spacers 431 and the second gate spacers 432 using any suitable deposition processes, and patterning the spacer material layers by any suitable patterning processes and/or etching processes. Other suitable materials and/or processes for forming the gate spacer features 43 are within the contemplated scope of the present disclosure.

After forming the gate structures 40, portions of the nanosheet stack 200 are exposed from the gate structures 40.

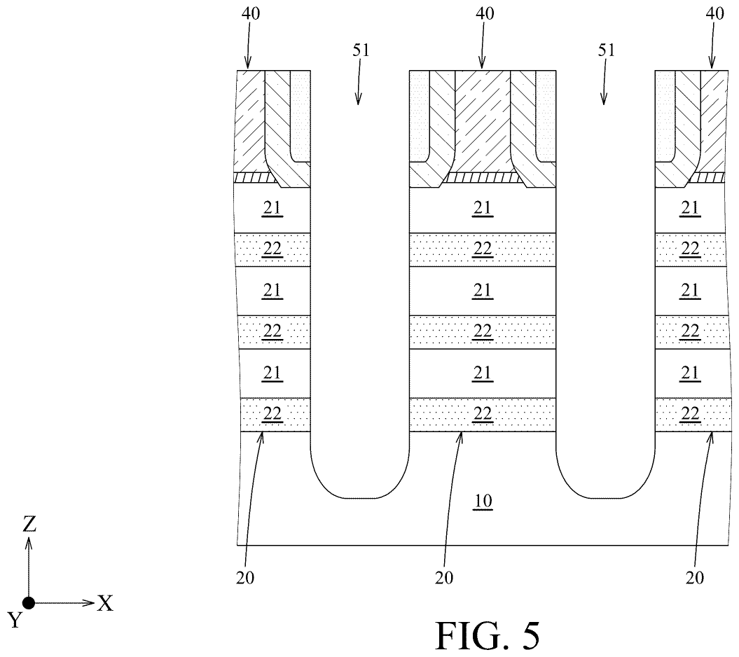

Referring to FIG. 5, step 101 may further include forming source/drain recesses 51.

The source/drain recesses 51 may be formed by performing a patterning process to remove the exposed portions of the nanosheet stack 200 (see also FIG. 4). As such, the nanosheet stack 200 is formed into a plurality of stack portions 20, while channel layers 210 and sacrificial layers 220 are respectively formed into channel features 21 and sacrificial features 22. In some embodiments, the patterning process may also remove surface portions of the substrate 10, such that each of the source/drain recesses 51 may extend from an upper surface of the corresponding stack portions 20 and penetrate into the substrate 10. The patterning process may be performed by any suitable patterning processes and/or etching processes, while the dummy gates may be protected by the masks respectively disposed on the dummy gates. In some embodiments, after forming the source/drain recesses 51, a replacement process was performed to replace the second semiconductor material in the sacrificial features 22 with a dielectric material (e.g., silicon oxide or other suitable materials). Since such replacement process may be performed or may be omitted according to practical needs, and since the elements obtained after the replacement process also have a configuration substantially same as that of the sacrificial features, the term “sacrificial features 22” (which may be made of the second semiconductor material or the dielectric material) are also used in the following steps.

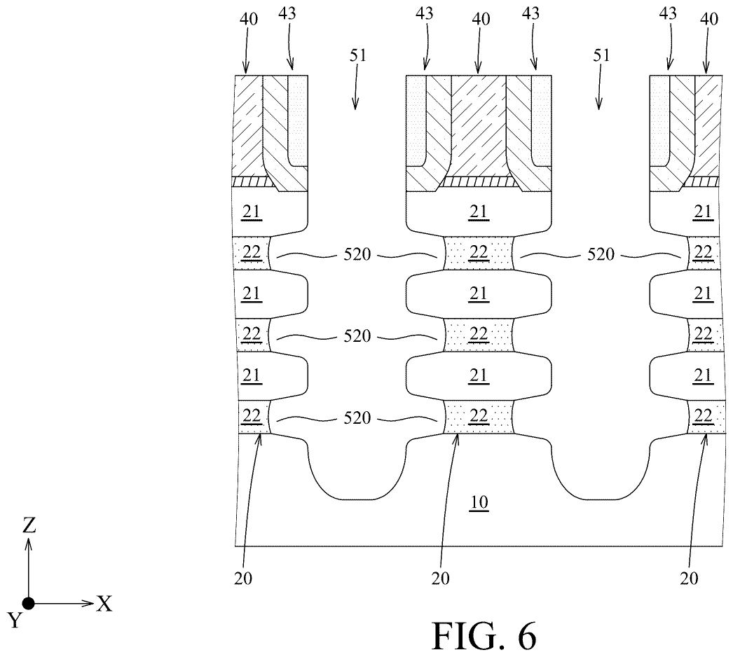

Referring to FIGS. 6 to 8, step 101 may further include forming inner spacers 52.

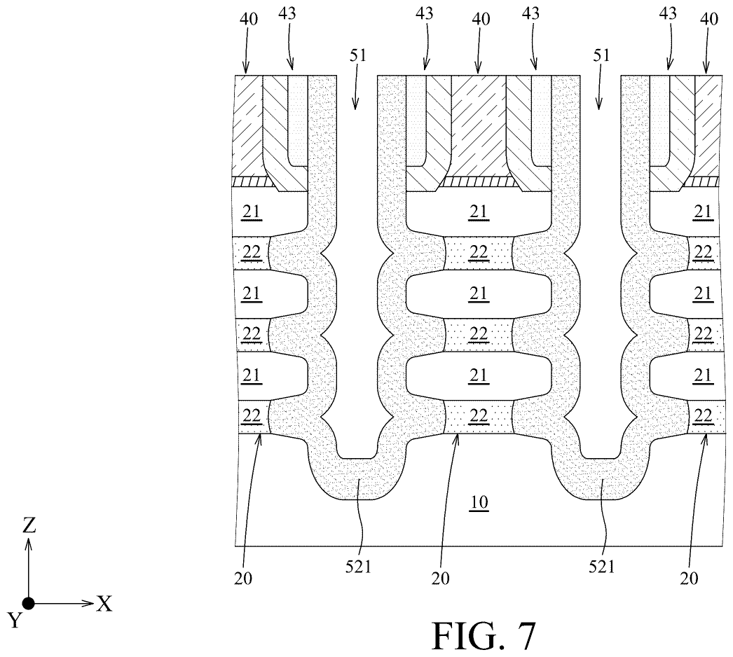

Forming the inner spacers 52 may include removing end regions of each of the sacrificial features 22 that are located beneath the gate spacer features 43 of a corresponding one of the gate structures 40 to form spacer recesses 520 (see FIG. 6); forming a spacer material layer 521 over the structure shown in FIG. 6 to fill the spacer recesses 520 (see FIGS. 6 and 7) using any suitable deposition processes; and removing excess portions of the spacer material layer 521 using any suitable etching processes, thereby forming the inner spacers 52 (see FIGS. 7 and 8). In some embodiments, the spacer material may include a dielectric material, such as silicon oxide, silicon nitride, silicon oxynitride, silicon carbide, or the likes, or combinations thereof. Other suitable materials and/or processes for forming the inner spacers 52 are within the contemplated scope of the present disclosure.

After forming the inner spacers 52, the patterned structure as shown in FIG. 8 is formed on the substrate 10.

Exemplarily, in the patterned structure, the channel features 21 may include channel features 21A, 21B and 21C; the sacrificial features 22 may include sacrificial features 22A, 22B and 22C; and the inner spaces 52 may include inner spacers 52A, 52B, 52C. Number of the channel features in each of the stack portions 20 depends on number of the first nanosheet layers in forming the nanosheet material stack discussed in step 101. Number of the sacrificial features in each of the stack portions 20, and the number of inner spacers depend on number of the second nanosheet layers in forming the nanosheet material stack.

Referring to a boxed region (L) shown in FIG. 8, only some of the channel features 21, the sacrificial features 22 and the inner spacers 52, and one of the source/drain recesses 51 are illustrated. As illustrated by the boxed region (L), the two channel features 21A are spaced apart from each other by the source/drain recess 51; the two channel features 21B are disposed respectively beneath the two channel features 21A, and are spaced apart from each other by the source/drain recess 51; and the two channel features 21C are disposed respectively beneath the two channel features 21A (and the two channel features 21B), and are spaced apart from each other by the source/drain recess 51.

In addition, as illustrated by the boxed region (L), each of the two sacrificial features 22A is disposed between one of the two channel features 21A and a respective one of the two channel features 21B; each of the inner spacers 52A is disposed between the one of the two channel features 21A and the respective one of the two channel features 21B to separate a respective one of the two sacrificial features 22A from the source/drain recess 51; each of the two sacrificial features 22B is disposed between one of the two channel features 21B and a respective one of the two channel features 21C; each of the inner spacers 52B is disposed between the one of the two channel features 21B and the respective one of the two channel features 21C to separate a respective one of the two sacrificial features 22B from the source/drain recess 51; each of the two sacrificial features 22C is disposed beneath a respective one of the two channel features 21C; and each of the inner spacers 52C is disposed beneath one of the two channel features 21C to separate a respective one of the two sacrificial features 22C from the source/drain recess 51.

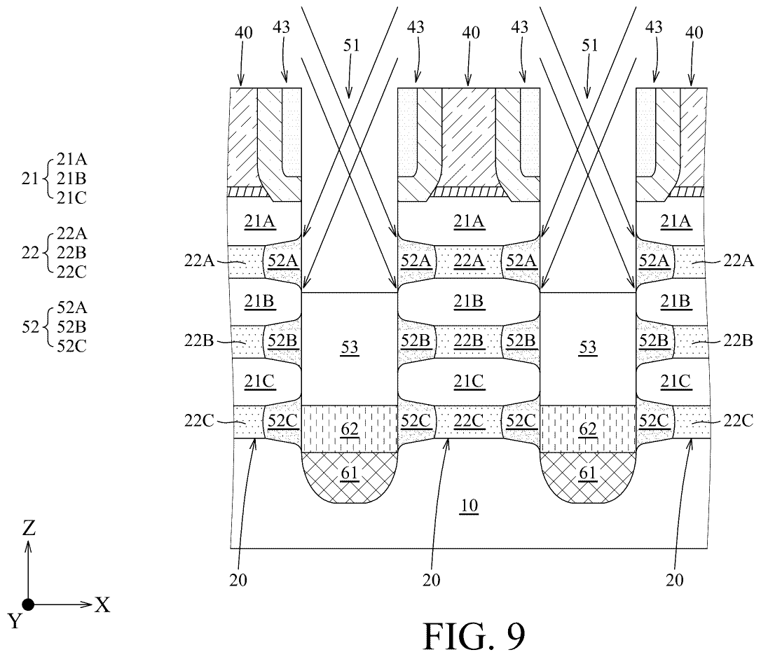

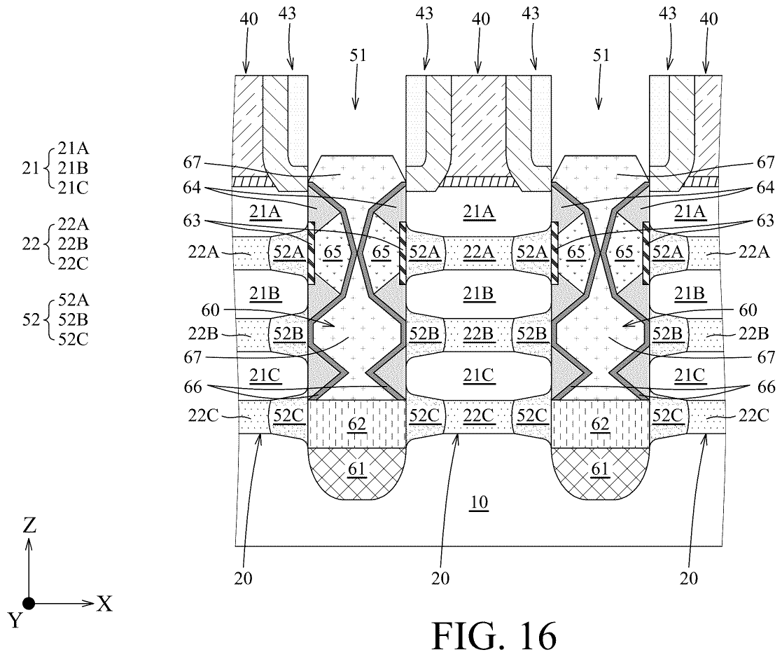

FIGS. 9 to 16 cooperatively illustrate processes for forming source/drain portions 60 (see FIG. 16) of the semiconductor structure in accordance with some embodiments. In some embodiments, the resultant semiconductor structure is a p-type device, and the source/drain portions therein are p-type source/drain portions. To ensure good device performance, the p-type source/drain portions are configured to provide a compressive stress to channel features of the p-type semiconductor structure, i.e., the channel features are compressively strained. That is, the p-type semiconductor structure may have an improved performance due to presence of a highly compressive stress in the channel features. FIGS. 9 to 16 illustrate formation of the p-type source/drain portions 60 that are capable to induce a highly compressively stress in the channel features 21A, 21B, 21C. With regard to the descriptions of FIGS. 9 to 16, since each of the source/drain portions 60 is formed in the same manner, only one of the source/drain portions 60 (which is formed in the source/drain recess 51 at the boxed region (L, see FIG. 8)) and the elements for forming the one of the source/drain portions 60, are described hereinafter for simplicity.

Referring to FIG. 1 and the examples illustrated in FIGS. 9 to 12, the method 100 proceeds to step 102, where growth promotion elements 63 are respectively formed at predetermined ones of the inner spacers 52. In this exemplary embodiment, the predetermined ones of the inner spacers are the inner spacers denoted by the numeral 52A.

Referring to FIG. 9, step 102 may include sequentially forming a bottom epitaxial layer 61, a flexible bottom isolation (FBI) feature 62 (which may be referred to as a bottom isolation 62), and a first blocking layer 53 at a bottom of the source/drain recess 51. In some embodiments, the FBI feature 62 is formed to shield the inner spacers 52C. In some other embodiments, the inner spacers 52C are not shielded by the FBI feature 62.

The bottom epitaxial layer 61 may be referred to as L0 of the source/drain portion 60 (see FIG. 16). The bottom epitaxial layer 61 may include silicon, but is not limited thereto. In some embodiments, the bottom epitaxial layer 61 is free of germanium. In certain embodiments, the bottom epitaxial layer 61 is formed using an epitaxial growing process, but is not limited thereto. Other suitable materials or processes for forming the bottom epitaxial layer 61 are within the contemplated scope of the present disclosure.

The FBI feature 62 is configured to reduce fringing capacitance of the nanosheet-type semiconductor structure. The FBI feature 62 may include a dielectric material, such as silicon oxide, silicon nitride, silicon carbide, silicon oxynitride, silicon oxycarbide, silicon carbon nitride, or the likes, or combinations thereof, but are not limited thereto. The FBI feature 62 may be formed by any suitable deposition process. Other suitable materials and/or processes for forming the FBI feature 62 are within the contemplated scope of the present disclosure.

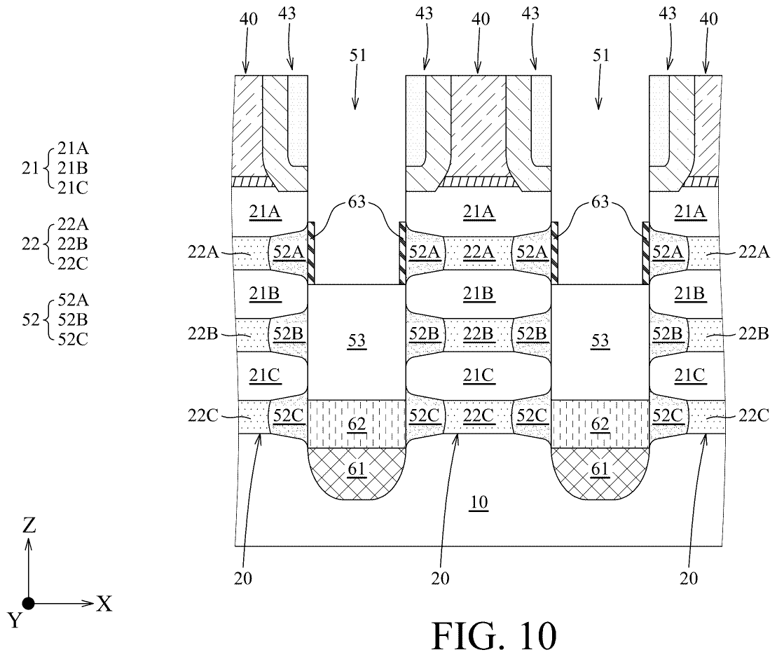

The first blocking layer 53 is configured to determine position of the growth promotion elements 63 (see FIG. 10) by adjusting height of the first blocking layer 53. Since the growth promotion elements 63 are to be formed at the inner spacers 52A, the first blocking layer 53 is formed to a level exposing the inner spacers 52A, and other elements that are located above the inner spacers 52A. The first blocking layers 53 may include any suitable polymers (e.g., a bottom anti reflective coating (BARC), but is not limited thereto), or amorphous carbon, or the likes, or combinations thereof. The first blocking layer 53 may be formed using any suitable deposition process. Other suitable materials and/or processes for forming the first blocking layer 53 are within the contemplated scope of the present disclosure.

Referring to FIG. 10, step 102 may further include performing a surface treatment to the predetermined inner spacers 52 by forming the growth promotion elements 63 thereon.

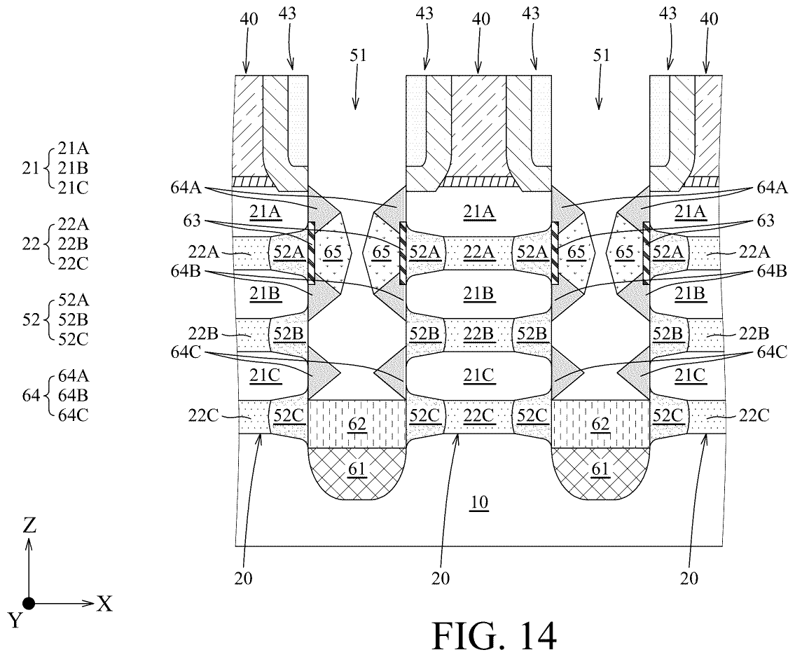

In some embodiments, the surface treatment is a low energy implantation process such that a growth promotion material (for forming the growth promotion elements 63) is deposited onto surfaces of the inner spacers 52A. In some embodiments, a source for the low energy implantation process is or includes a germanium source, and the growth promotion material is substantially made of germanium, a Ge-including material, such as silicon germanium, or other suitable semiconductor materials, but are not limited thereto. In some embodiments, the treatment may be performed with an energy level that is less than approximately 5 kV, such that the implantation treatment merely treats and deposits the Ge-including material at surfaces of the inner spacers 52A, but not implanting Ge ion into interior of the inner spacers 52A. Therefore, Ge content, if any, at the interior of the inner spacers 52A should remain substantially the same before and after the implantation process. Please note that the growth promotion elements 63 are desired to be formed mainly at surfaces of the inner spacers 52A. Any of the growth promotion material that is deposited on elements other than the inner spacers 52A (e.g., on the channel features 21A, the gate spacer features 43, or other elements that are exposed to the source/drain recess 51) is considered an excess portion (such excess portion is not shown in the figures) and is to be removed subsequently. Therefore, in certain embodiments, the implantation treatment is directional and may be performed at a tilted angle to target at mainly the inner spacers 52A (i.e., the implantation treatment may be also referred to as a directional implantation process). As shown in FIG. 9, the arrows illustrate direction of the implantation process. Other parameters for performing the implantation process may be adjusted according to practical needs. In some embodiments, the growth promotion elements 63 are made of germanium, while in some other embodiments, the growth promotion elements 63 may be made of other suitable materials which are different from the material of the channel features 21, and which facilitate epitaxial layers 65 (see FIG. 14) to be selectively formed thereon.

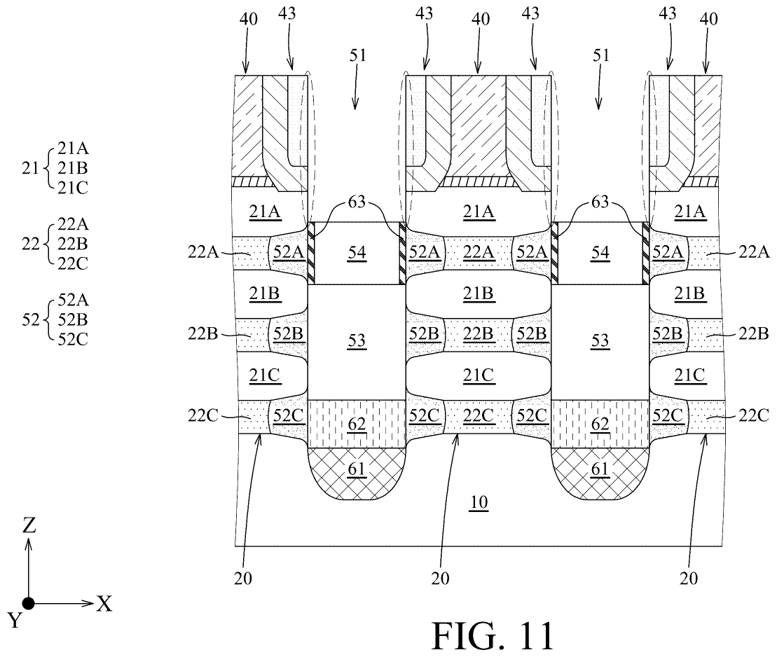

Referring to FIG. 11, step 102 may further include performing a cleaning process to remove the excess portion of the growth promotion material.

A second blocking layer 54 is formed prior to performing the cleaning process. The regions denoted by dotted lines in FIG. 11 illustrate possible locations of the excess portion of the growth promotion material.

The second blocking layer 54 is configured to (i) cover and protect the growth promotion elements 63, i.e., portions of the growth promotion material that are respectively deposited on the predetermined inner spacers 52A, and (ii) to expose the excess portion of the growth promotion material. Possible materials and processes for forming the second blocking layer 54 are similar to those for forming the first blocking layer 53, and thus details thereof are omitted for the sake of brevity. The second blocking layer 54 may be the same or different from the first blocking layer 53.

The cleaning process may be any suitable etching process that removes the growth promotion material of the excess portion without damaging the underlying elements, e.g., the gate spacer features 43, the channel features 21A, but are not limited thereto. Other suitable cleaning processes are within the contemplated scope of the present disclosure.

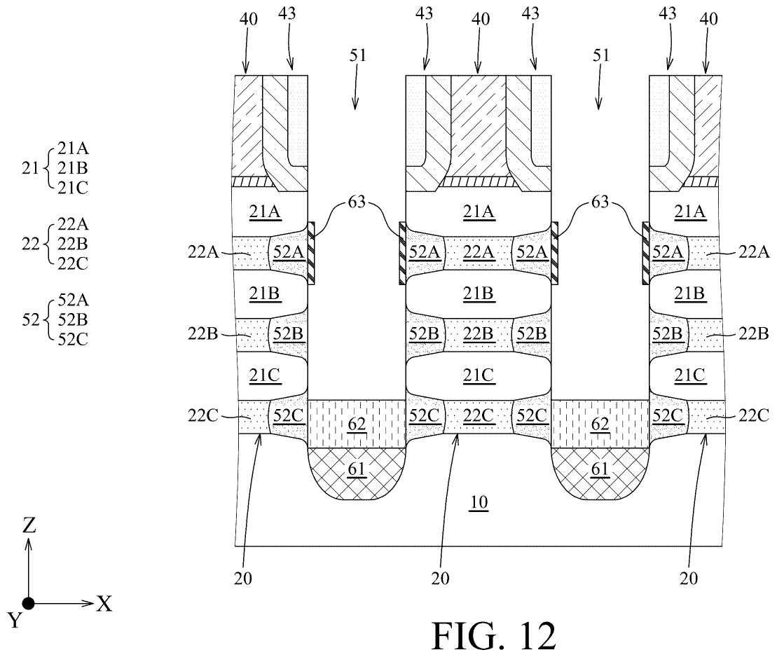

Referring to FIG. 12, step 102 may further include removing the first blocking layer 53 and the second blocking layer 54 (see FIG. 11).

The first and second blocking layers 53, 54 may be removed using any suitable processes, e.g., an ashing process, but is not limited thereto. Other suitable removing processes are within the contemplated scope of the present disclosure.

FIG. 12 shows a resultant structure after performing step 102. Specifically, the growth promotion elements 63 are respectively formed on the predetermined ones of the inner spacers 52, i.e., in this exemplary embodiment, on the inner spacers 52A, but not on the inner spacers 52B, 52C (or at the channel features 21A, 21B, 21C). The growth promotion material (e.g., germanium) inside the growth promotion elements 63 facilitates adsorption of precursors for epitaxial growth of epitaxial layers (e.g., germanium-including epitaxial layers) that are to be formed in subsequent processes, so as to increase growing rate of the epitaxial layers formed on the growth promotion elements 63. In some embodiments, the growth promotion elements 63 may have a germanium content ranging from about 20 atomic percentage to about 100 atomic percentage based on 100 atomic percentage of atoms present in the growth promotion elements 63, so as to effectively promote formation of the epitaxial layers 65 in subsequent step. In some embodiments, the growth promotion elements 63 are each formed as a continuous layer, and with a sufficient thickness (measured along the longitudinal direction (X)), so as to ensure sufficient amount of the growth promotion material is present at the predetermined inner spacers 52A, so as to promote adsorption efficiency of the precursors onto the growth promotion elements 63. The growth promotion elements 63 may not be formed too thick (e.g., greater than approximately 1 nm), since the cleaning process as aforementioned may undesirably damage elements other than the excess portion of the growth promotion material. In some embodiments, the growth promotion elements 63 may have the thickness ranging from about 0.2 nm to about 1.0 nm, but is not limited thereto. Other suitable thickness ranges of the growth promotion elements 63 are within the contemplated scope of the present disclosure. With the configuration of the growth promotion elements 63, the inner spacers 52A are surface-treated to promote epitaxial growth of epitaxial layers thereon, while the remaining inner spacers 52B, 52C do not have such merit.

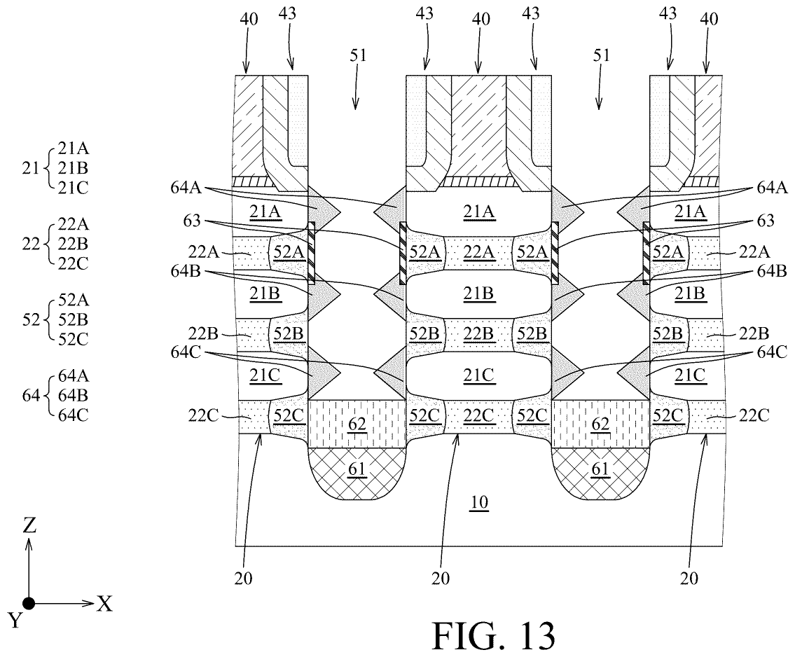

Referring to FIG. 1 and the examples illustrated in FIGS. 13 to 14, the method 100 proceeds to step 103, where epitaxial layers 65 are formed on the growth promotion elements 63 opposite to the predetermined inner spacers 52A, respectively.

Referring to FIG. 13, step 103 may include forming epitaxial regions 64 on the channel features 21A, 21B, 21C, respectively. The epitaxial regions 64 may adjust junction profile between the channel features 21A, 21B, 21C and the source/drain portion 60. In some embodiments, the epitaxial regions 64 may include silicon. In certain embodiments, the epitaxial regions 64 may be doped with boron at a dopant concentration ranging from about 5×10¹⁹ atom/cm³ to about 3×10²¹ atom/cm³, but is not limited thereto. In some embodiments, the epitaxial regions 64 may be made of boron-doped silicon, which is also referred to as selective Si: B (SSB). In certain embodiments, the epitaxial regions 64 are substantially free of germanium. In some embodiments, the epitaxial regions 64 are formed using, for example, an epitaxial growing process, but is not limited thereto. Other suitable materials and/or dopant concentration and/or processes for forming the epitaxial regions 64 are within the contemplated scope of the present disclosure.

Referring to FIG. 14, step 103 may further include forming the epitaxial layers 65 on the predetermined inner spacers 52A.

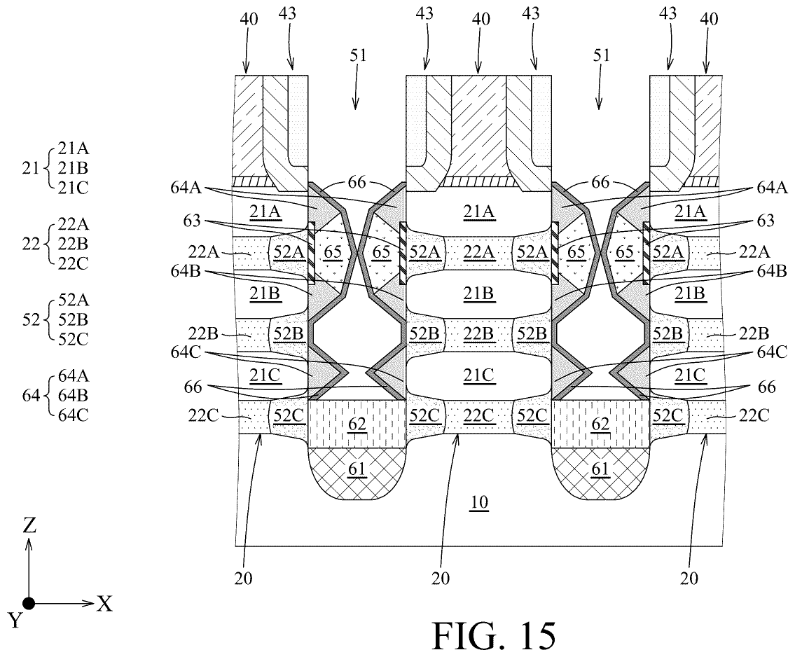

The epitaxial layers 65 may include silicon germanium. In some embodiments, the epitaxial layers 65 may have a germanium content ranging from about 5 atomic percentage to about 30 atomic percentage based on 100 atomic percentage of atoms present in the epitaxial layers 65. The epitaxial layers 65 may be also referred to as a low-germanium-silicon (LGS) layer. In some embodiments, the epitaxial layers 65 may have a thickness ranging from about 4 nm to about 15 nm (measured along the longitudinal direction (X), the transverse direction (Y), or the vertical direction (Z)), but is not limited thereto. When the epitaxial layers 65 are too thin (e.g., less than about 4 nm), such epitaxial layers 65 cannot promote merging and bridging of epitaxial layers 66 (see FIG. 15). When the epitaxial layers 65 are too thick (e.g., greater than about 15 nm), volume of epitaxial layer 67 (see FIG. 16) is reduced and germanium content in the source/drain portion 60 (see FIG. 16) may be insufficient to provide a compressive stress to the channel features 21A, 21B, 21C. In some embodiments, the epitaxial layers 65 may be doped with p-type impurities. Other suitable materials and/or processes for forming the epitaxial layers 65 are within the contemplated scope of the present disclosure.

The epitaxial layers 65 may be formed using an epitaxial growing process. In the epitaxial growing process, since the inner spacers 52B and the FBI features 62 are made of dielectric material(s), silicon germanium for forming the epitaxial layers 65 therefore may not grow on the inner spacers 52B and the FBI features 62. Instead, silicon germanium for forming the epitaxial layers 65 is grown on the epitaxial regions 64 that are made of boron-doped silicon. As shown in FIG. 14, the epitaxial regions 64 may include epitaxial regions 64A, 64B, 64C. Silicon germanium grown between each of the epitaxial regions 64A and a respective one of the epitaxial regions 64B merge and continue to grow, and similarly, silicon germanium between each of the epitaxial regions 64B and a respective one of the epitaxial regions 64C merge and continue to grow (not shown in the figures). It is noted that, after merging, a lateral growth (in the longitudinal direction (X)) of the silicon germanium between each of the epitaxial regions 64A and the respective epitaxial layer 64B is promoted by a respective one of the growth promotion elements 63. The growth promotion material present in the growth promotion elements 63 facilitates adsorption of some of precursor molecules for forming the epitaxial layers 65 (e.g., a Ge precursor such as GeH₄) on the growth promotion elements 63, so that silicon germanium formed on the growth promotion elements 63 readily grow along the longitudinal direction (X). A growth rate of the silicon germanium between each of the epitaxial regions 64A and the respective epitaxial layer 64B (i.e., over a respective one of the inner spacers 52A that are surface-treated) is much higher than a growth rate of the silicon germanium between each of the epitaxial regions 64B and a respective one of the epitaxial layer 64C (i.e., over the inner spacers 52B that are not surface-treated). A small amount of the silicon germanium grown between the epitaxial regions 64B and the epitaxial regions 64C and at the epitaxial regions 64C is not shown in the figures and will be ignored in the following discussion. That is, it can be considered that the epitaxial layers 65 are mainly formed at the inner spacers 52A (more specifically, on the growth promotion elements 63 between the epitaxial regions 64A, 64B) in a selective manner with respective to the other inner spacers 52B, 52C. In addition, with the provision of the growth promotion elements 63, process variation, e.g., random growth of the epitaxial layers 65 at different inner spacers are greatly reduced.

Referring to FIG. 1 and the example illustrated in FIG. 15, the method 100 proceeds to step 104, where the epitaxial layers 66 are formed. The epitaxial layers 66 may be referred to as L1 of the source/drain portion 60 (see FIG. 16).

The epitaxial layers 66 may include silicon germanium. A germanium content of the epitaxial layers 66 is higher than the germanium content of the epitaxial layers 65. In some embodiments, the epitaxial layers 66 may have a germanium content ranging from about 10 atomic percentage to about 30 atomic percentage based on 100 atomic percentage of atoms present in the epitaxial layers 66. In some embodiments, the epitaxial layers 66 may be doped with p-type impurities. In some embodiments, the epitaxial layers 66 may have a thickness ranging from about 1 nm to about 4 nm, but is not limited thereto.

In some embodiments, the epitaxial layers 66 may be formed using an epitaxial growing process. Referring back to FIG. 14, at a level where the inner spacers 52A are located, with the configuration of the growth promotion elements 63 and the epitaxial layers 65, a first spaced-apart distance between the epitaxial layers 65 is relatively small. In contrast, a second spaced-apart distance between the inner spacers 52B is relatively large. In some embodiments, a difference between the first spaced-apart distance and the second spaced-apart distance may range from about 2 nm to about 12 nm. When the difference is too small (e.g., less than 2 nm), the epitaxial layers 66 may undesirably merge at the levels of both the inner spacers 52A, 52B, such epitaxial layers 66 are not effective in promoting epitaxial layer 67 to be grown from such epitaxial layers in the vertical direction (Z) (will be further explained in later paragraphs). The difference might not be too large, due to limitation of a width of the source/drain recess 51. In the epitaxial growth of the epitaxial layers 66, as shown in FIG. 15, parts of the epitaxial layers 66 that are grown at the level of the inner spacers 52A easily reach to each other and merge together due to the smaller first spaced-apart distance. In contrast, parts of the epitaxial layers 66 that are grown at the level of the inner spacers 52B are still spaced apart and do not merge. That is, the epitaxial layers 66 merely merge at the inner spacers 52A where the epitaxial layers 65 and the growth promotion elements 63 are formed, but not at the inner spacers 52B. Other suitable materials and/or processes for forming the epitaxial layers 66 are within the contemplated scope of the present disclosure.

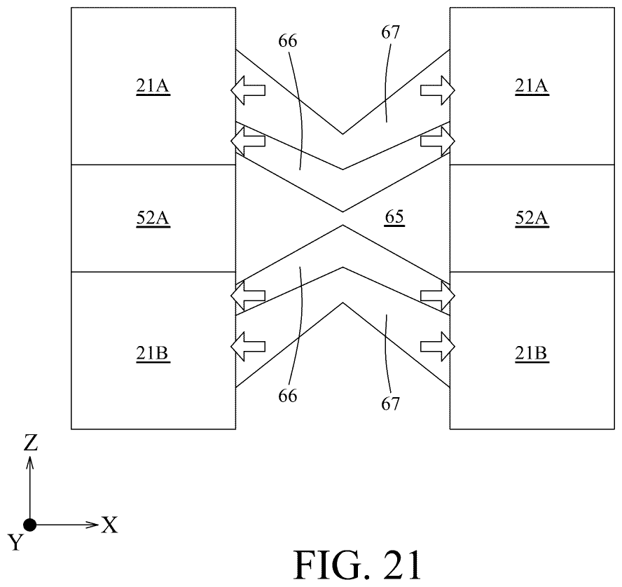

In this exemplary embodiment, the growth promotion elements 63 and the epitaxial layers 65, 66 cooperatively serve as a bridging epitaxial feature. The epitaxial layers 65, which are grown at a faster rate at the level of the predetermined inner spacers 52A, facilitate merging of the epitaxial layers 66 at the level of the predetermined inner spacers 52A, thereby obtaining the bridging epitaxial feature. Formation of the bridging epitaxial feature overcomes the issue that epitaxial layers being unable to grow vertically from the dielectric FBI feature 62. The bridging epitaxial feature, is configured to interconnect the two inner spacers 52A and to provide a growing base for the epitaxial layer 67 (see FIG. 16) to grow thereon in a vertical direction, i.e., along the vertical direction (Z). In some other embodiments, the epitaxial layers 65 merge and bridge the inner spacers 52A (see FIG. 21).

Referring to FIG. 1 and the example illustrated in FIG. 16, the method 100 proceeds to step 105, where the epitaxial layer 67 is formed. The epitaxial layer 67 may be referred to as L2 of the source/drain portion 60.

The epitaxial layer 67 may include silicon germanium. A germanium content of the epitaxial layer 67 is higher than the germanium content of the epitaxial layers 66. In some embodiments, the epitaxial layer 67 may have a germanium content greater than approximately 30 atomic percentage based on 100 atomic percentage of atoms present in the epitaxial layer 67. In some embodiments, the epitaxial layers 67 may be doped with p-type impurities. It is noted that the germanium content of each of the epitaxial layers 65, 66, 67 increases in a gradual manner.

In some embodiments, the epitaxial layer 67 may be formed using an epitaxial growth process, where precursor(s) for forming the epitaxial layers 67 may have access to a space beneath the bridging epitaxial feature along the transverse direction (Y). In the epitaxial growth process, silicon germanium for forming the epitaxial layer 67 is grown on the epitaxial layers 66. Specifically, the epitaxial layers 66 merge at the level of the predetermined inner spacers 52A to provide a continuously horizontal (in comparison with the parts of the epitaxial layers 66 at the level of the inner spacers 52B) surface for silicon germanium to grow thereon along the vertical direction (Z). As such, the epitaxial layer 67 is also referred to as the vertically grown epitaxial feature. Other suitable materials and/or processes for forming the epitaxial layers 67 are within the contemplated scope of the present disclosure. After completing step 105, the source/drain portion 60 of the semiconductor structure is obtained. The epitaxial layer 67 of the source/drain portion 60, with a relatively high germanium content and being systematically (effectively) grown in the vertical direction (Z), is conducive to provide a highly compressive stress to the channel features 21A, 21B and 21C.

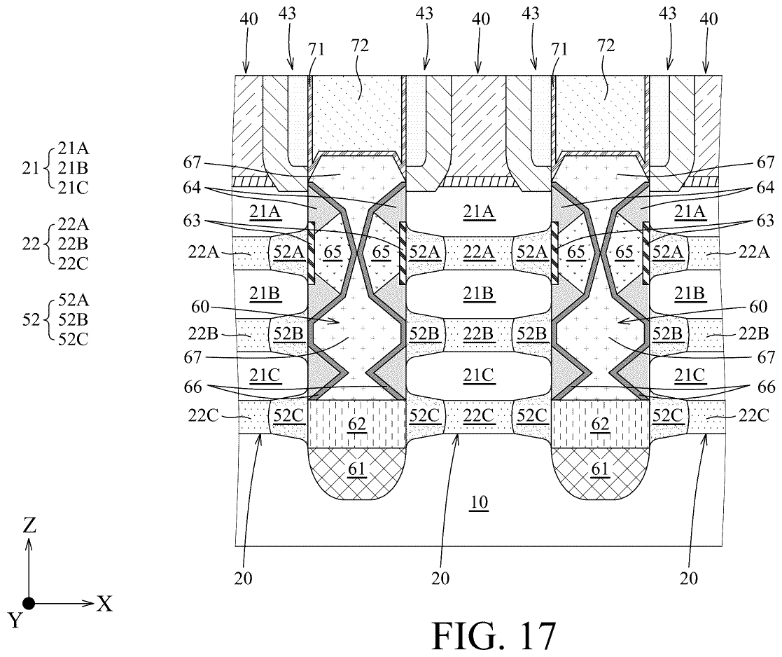

Referring to FIG. 1 and the example illustrated in FIG. 17, the method 100 proceeds to step 106, where a contact etch stop layer (CESL) 71 and an interlayer dielectric (ILD) 72 are sequentially formed on each of the source/drain portions 60.

Each of the CESL 71 and the ILD 72 may include a dielectric material such as silicon oxide, silicon nitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or the like, or combinations thereof. The CESL 71 and the ILD 72 may include different dielectric materials. Each of the CESL 71 and the ILD 72 may be formed by forming two dielectric layers for forming the CESL 71 and the ILD 72 over the structure shown in FIG. 16 using any suitable deposition process, followed by a planarization process (e.g., CMP) to remove an excess of the two dielectric layers to expose the dummy gates of the gate structures 40. Therefore, the mask (not shown) which is formed over each of the dummy gates of the gate structures 40 are removed in the planarization process. Other suitable materials and/or processes for forming the CESL 71 and/or the ILD 72 are within the contemplated scope of the present disclosure.

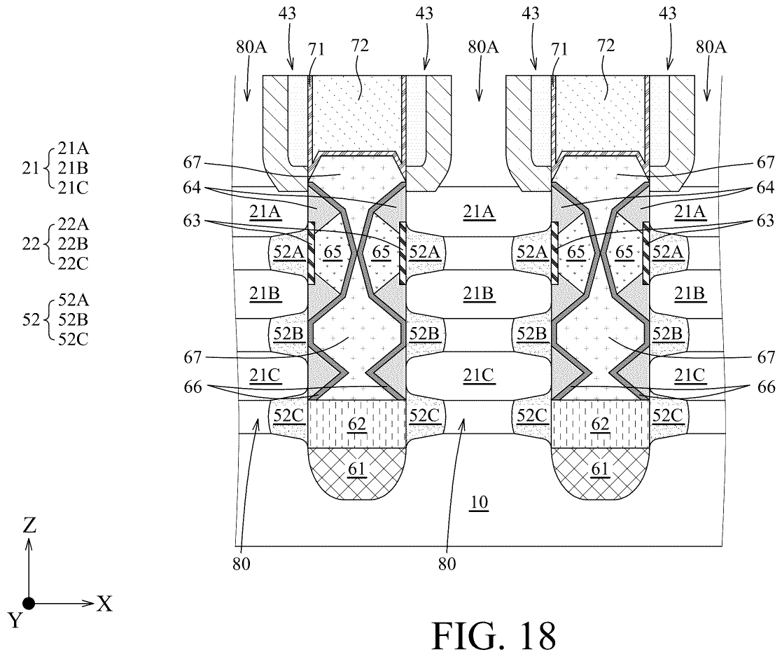

Referring to FIG. 1 and the examples illustrated in FIGS. 18 and 19, the method 100 proceeds to step 107, where active gates 83 are formed.

Referring to FIG. 18, step 107 may include removing the dummy gates of the gate structures 40 (see FIG. 17), and removing the sacrificial features 22A, 22B and 22C to form cavities 80. Any suitable processes, such as one or more etching processes, may be adopted to remove the dummy gates and the sacrificial features 22A, 22B and 22C.

Referring to FIG. 19, step 107 may further include forming the active gates 83 respectively in the cavities 80 using any suitable deposition processes. Each of the active gates 83 includes an active gate dielectric 81 and an active gate electrode 82.

In some embodiments, the active gate dielectric 81 may include a high dielectric constant material, such as a hafnium-based dielectric material, or the like, but is not limited thereto. In some embodiments, the active gate electrode 82 may include a conductive material such as a metal (such as tungsten, aluminum, cobalt, ruthenium, titanium, tantalum, molybdenum, nickel, platinum, copper, and so on), a metal-containing nitride, a metal-containing silicide, a metal-containing carbide, or the likes, but are not limited thereto.

In some embodiments, forming the active gates 83 may include sequentially depositing a first material layer (not shown, for forming the active gate dielectric 81) and a second material layer (not shown, for forming the active gate electrode 82) in each of the cavities 80, followed by a planarization process, (e.g., a CMP process, but is not limited thereto) so as to remove an excess amount of the first and second material layers, thereby forming the active gate dielectric 81 and the active gate electrode 82. Other suitable materials and/or processes for forming the active gate dielectric 81 and/or the active gate electrode 82 are within the contemplated scope of the present disclosure.

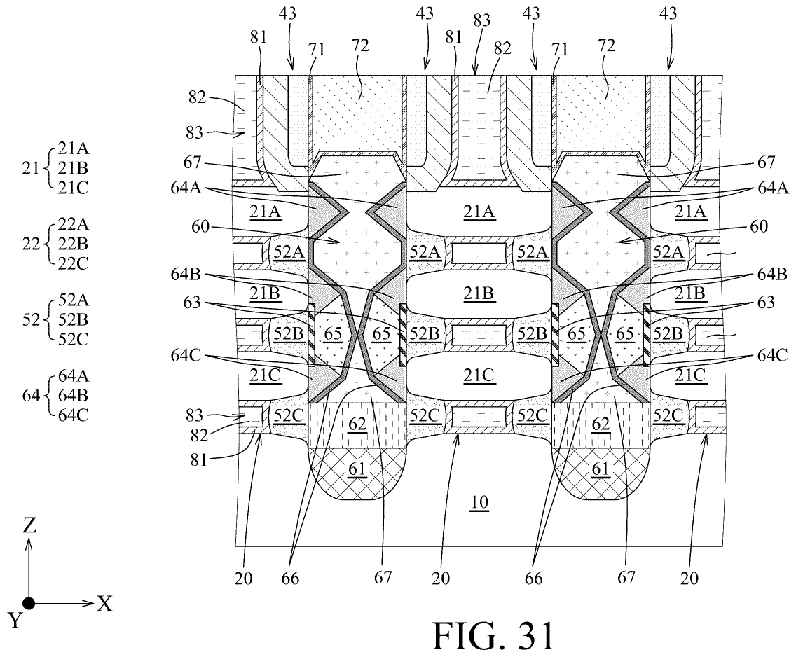

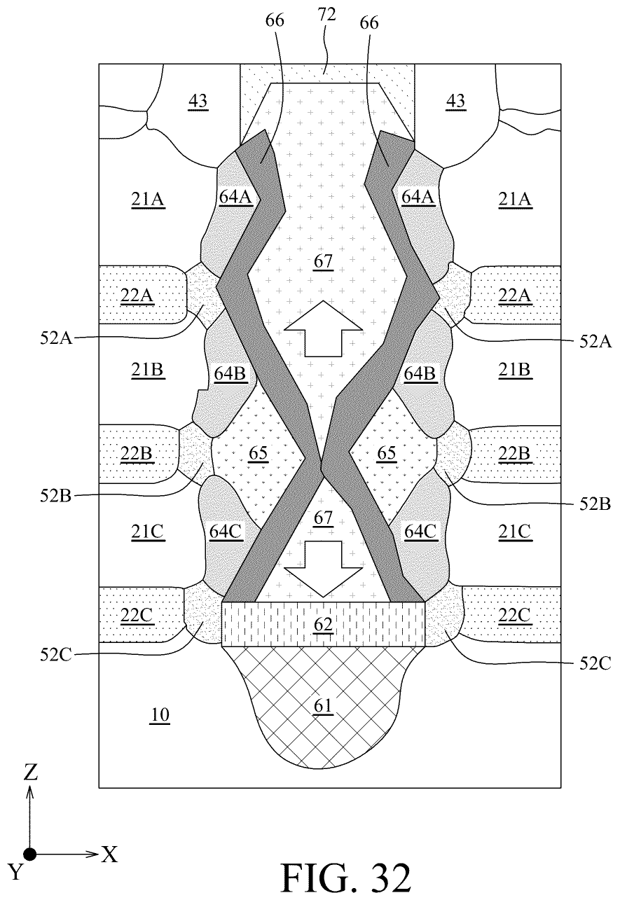

After completing step 106, the semiconductor structure in accordance with some embodiments is obtained. FIG. 20 is a schematic view of another semiconductor structure which is similar to that of FIG. 19 (the growth promotion elements 63 are not shown in FIG. 20), and which is shown to further illustrate the vertically grown epitaxial feature, i.e., the epitaxial layer 67. In the exemplary embodiments shown in FIGS. 19 and 20, the vertically grown epitaxial feature is formed in a mainly top-down approach, and the epitaxial layer 67 containing silicon germanium is grown from a relatively high level relative to the substrate 10. Such vertically grown epitaxial feature is noted to generate a relatively high level of compressive stress (in comparison with the structure shown in FIGS. 31 and 32 where the vertically grown epitaxial feature is formed in a mainly bottom-up approach), such that the channel features 21A, 21B, 21C are more compressively strained, resulting in the semiconductor structure having an improved performance.

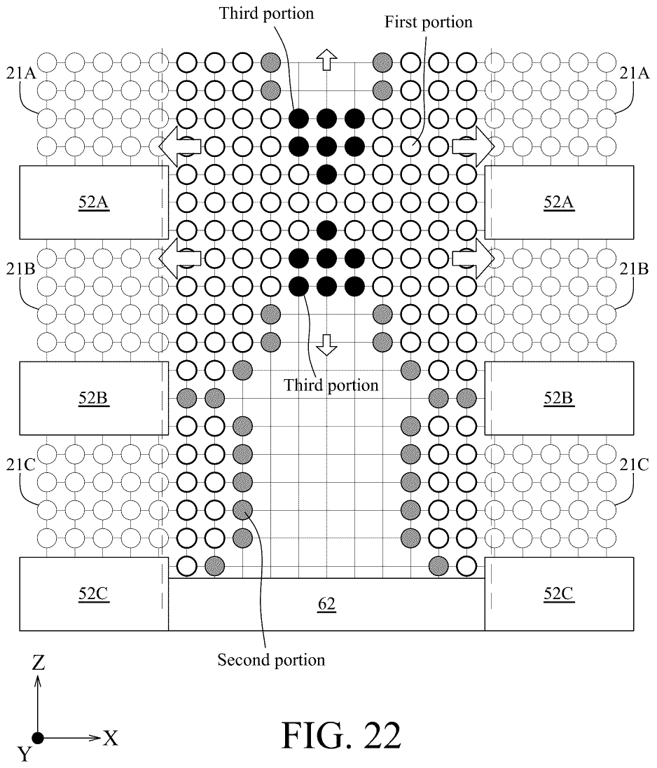

FIG. 21 is a schematic diagram of another semiconductor structure in accordance with some other embodiments, showing that the epitaxial layers 65 merge and bridge to interconnect the predetermined inner spacers 52A (some of the elements, for example, the growth promotion elements 63, are not shown in FIGS. 21 and 22). In such case, the growth promotion elements 63 and the epitaxial layers 65 serve as the bridging epitaxial feature, while both the epitaxial layers 66, 67 serve as the vertically grown epitaxial feature and are grown from the epitaxial layers 65 in the vertical direction (Z). The epitaxial layers 66, 67 shown in FIG. 21, similar to those shown in FIGS. 2 to 20, cooperatively generate a compressive stress in the channel features 21A, 21B, 21C (the arrows indicates direction of the compressive stress). Referring to FIG. 22, first portions may include the growth promotion elements 63, the epitaxial regions 64, the epitaxial layers 65 and a first part of the epitaxial layers 66; second portions may include a second part of the epitaxial layers 66 and are grown around the first portions; and third portions may include a third part of the epitaxial layers 66 and the epitaxial layer 67, and are grown vertically. With the provision of the first portions (including the bridging epitaxial feature), the vertically grown epitaxial feature (having a relatively large amount of germanium) can apply the compressive stress to the channel features 21A, 21B, 21C.

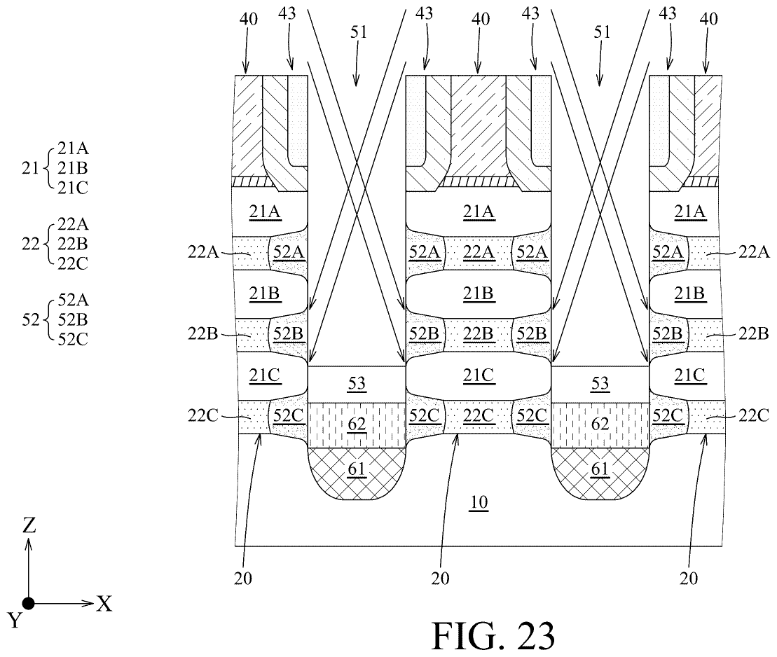

In the above embodiments, the epitaxial layers 65 or 66 of the bridging epitaxial feature merge at the level of the inner spacers 52A, which are the topmost ones of the inner spacers 52. In some other embodiments, the epitaxial layers 65 or 66 may also merge at the level of other ones of the inner spacers 52 based on practical needs and product specification. FIGS. 23 to 33 demonstrate the epitaxial layers 65 or 66 merging at, for example, the inner spacers 52B.

FIGS. 23 to 32 are schematic views that are respectively similar to those of FIGS. 9 to 16 and 19 to 20, except that in order to permit merging and bridging of the epitaxial layers 65 or 66 at the level of the inner spacers 52B, the inner spacers 52B serve as the predetermined ones of the inner spacers 52, and the growth promotion elements 63 and the epitaxial layers 65 are formed at the inner spacers 52B. Unless otherwise specified, details of the processes in achieving the structures of FIGS. 23 to 31 are similar to those described with reference to FIGS. 9 to 19, and thus details thereof are omitted for the sake of brevity.

Referring to FIG. 23, different from the example illustrated in FIG. 9, the first blocking layer 53 is formed to a level exposing the inner spacers 52B, and other elements that are located above the inner spacers 52B.

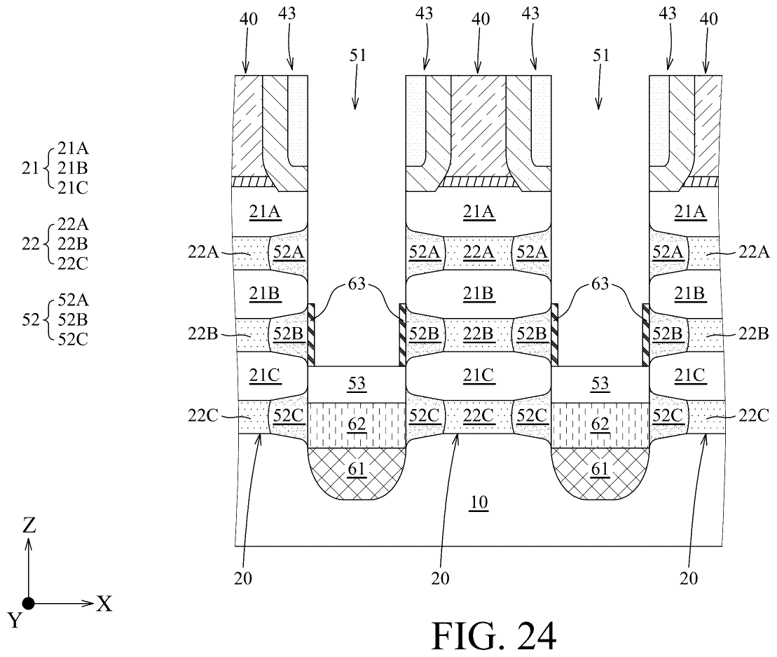

Referring to FIG. 24, different from the example illustrated in FIG. 10, during the surface treatment, the low energy implantation process is performed at a tilted angle to target at mainly the inner spacers 52B (as shown by the arrows in FIG. 23), such that the growth promotion material for forming the growth promotion elements 63 can be deposited on the inner spacers 52B. The excess portion of the growth promotion material (e.g. the growth promotion material that is deposited on the channel features 21A, 21B, the inner spacers 52A and the gate features 43) is not shown in the figures.

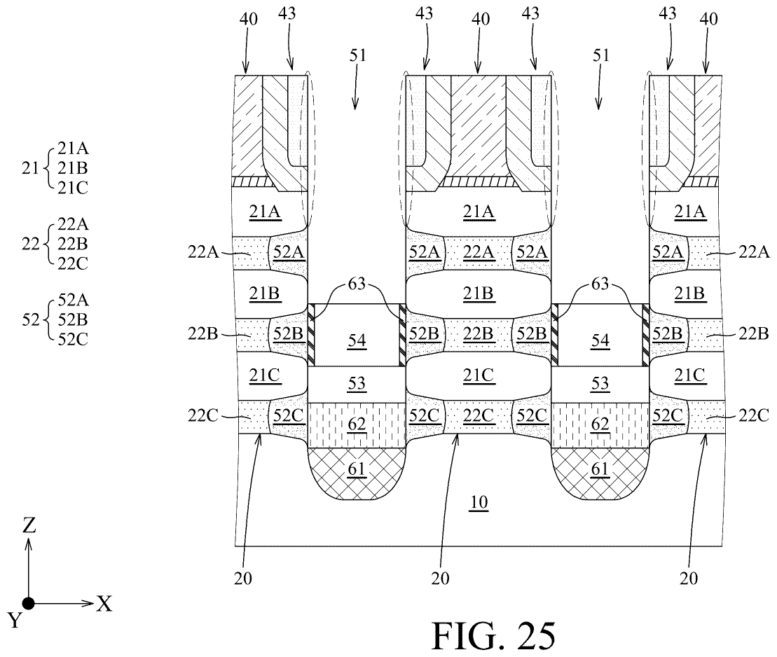

Referring to FIG. 25, different from the example illustrated in FIG. 11, the second blocking layer 54 is formed to protect the growth promotion elements 63 at the inner spacers 52B, and the cleaning process is performed to remove the excess portion of the growth promotion material. The regions denoted by dotted lines in FIG. 25 illustrate possible locations of the excess portion of the Ge-including material.

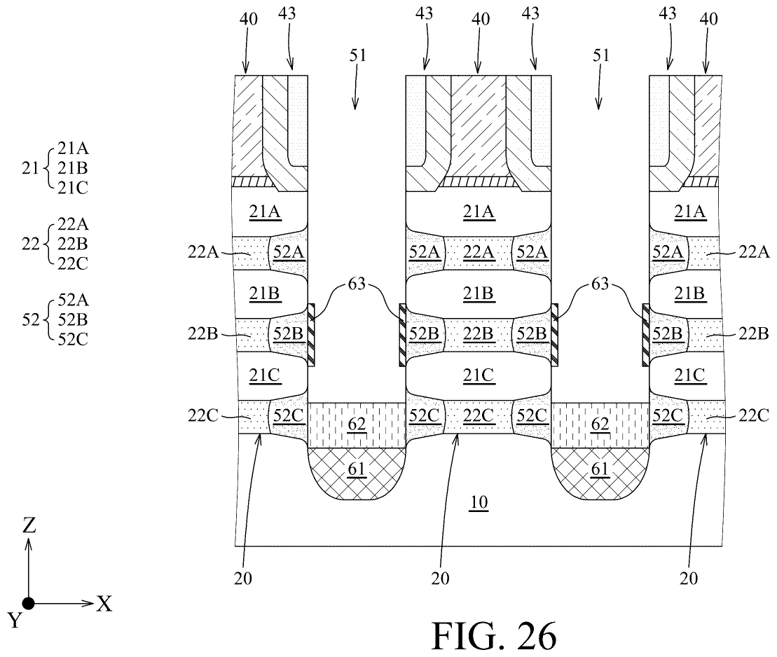

Referring to FIG. 26, after removing the first blocking layer 53 and the second blocking layer 54, in the resultant structure obtained thereby, the growth promotion elements 63 are formed at the inner spacers 52B (instead of at the inner spacers 52A as illustrated in FIG. 12).

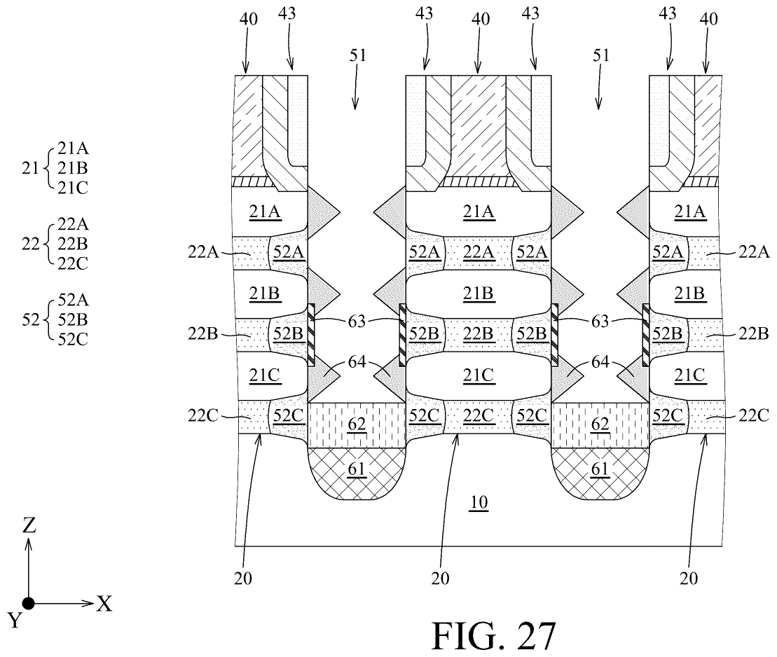

Referring to FIG. 27, formation of the epitaxial regions 64 is similar to the example shown in FIG. 13, and thus details thereof are omitted for the sake of brevity.

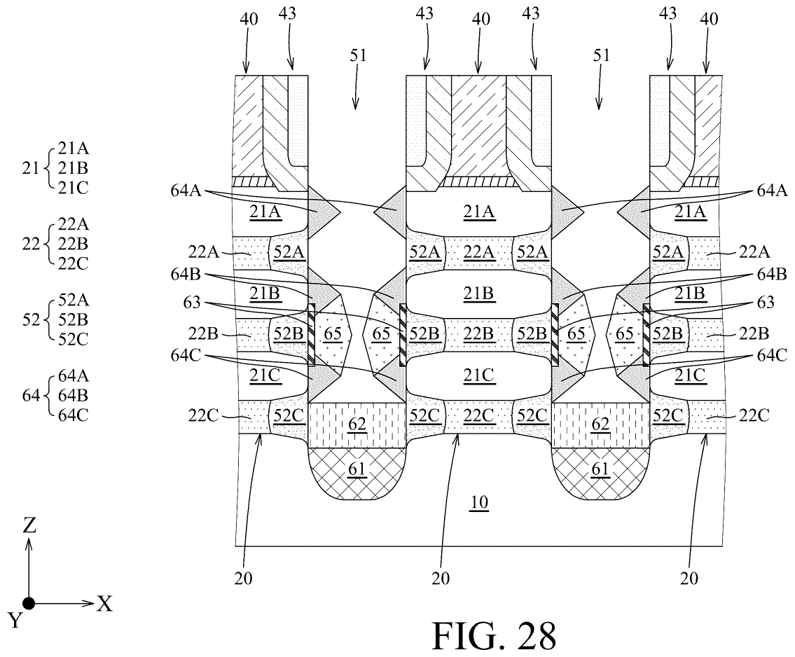

Referring to FIG. 28, different from the example illustrated in FIG. 14, the epitaxial layers 65 are formed at the predetermined inner spacers 52B. This is because the growth promotion elements 63 that promote lateral growth of silicon germanium (on the growth promotion elements 63) is formed on the inner spacers 52B but not on the other inner spacers (e.g., the inner spacers 52A). Therefore, the epitaxial layers 65 are formed on the predetermined inner spacers 52B in a selective manner with respect to the inner spacers 52A.

At a level where the inner spacers 52B are located, with the configuration of the growth promotion elements 63 and the epitaxial layers 65, a first spaced-apart distance between the epitaxial layers 65 is relatively small. In contrast, a second spaced-apart distance between the inner spacers 52A is relatively large.

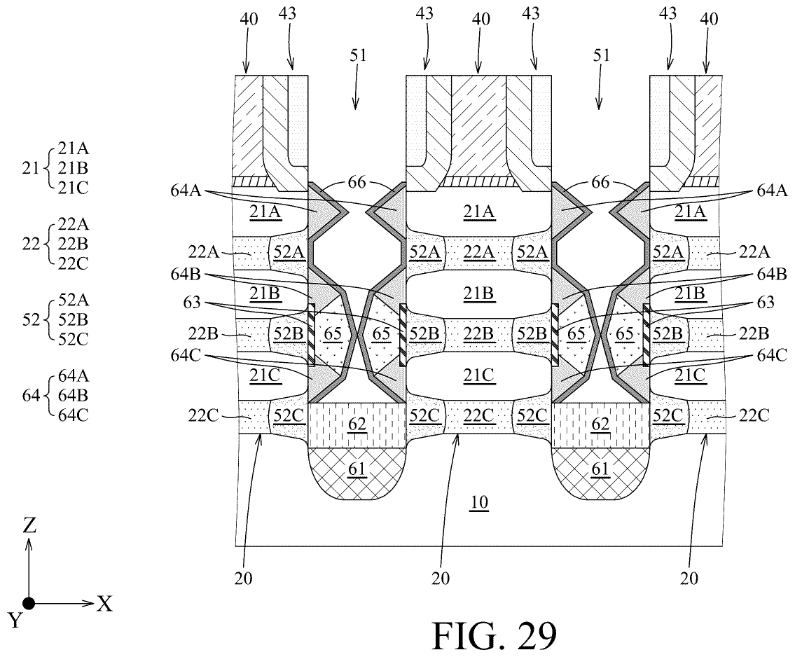

Referring to FIG. 29, different from the example illustrated in FIG. 15, in step 104, parts of the epitaxial layers 66 that are grown at the level of the inner spacers 52B easily reach to each other and merge together due to the smaller first spaced-apart distance. In contrast, parts of the epitaxial layers 66 that are grown at the level of the inner spacers 52A are still spaced apart and do not merge. That is, the epitaxial layers 66 merely merge at the level of the inner spacers 52B where the epitaxial layers 65 and the growth promotion elements 63 are formed, but not at the level of the inner spacers 52A.

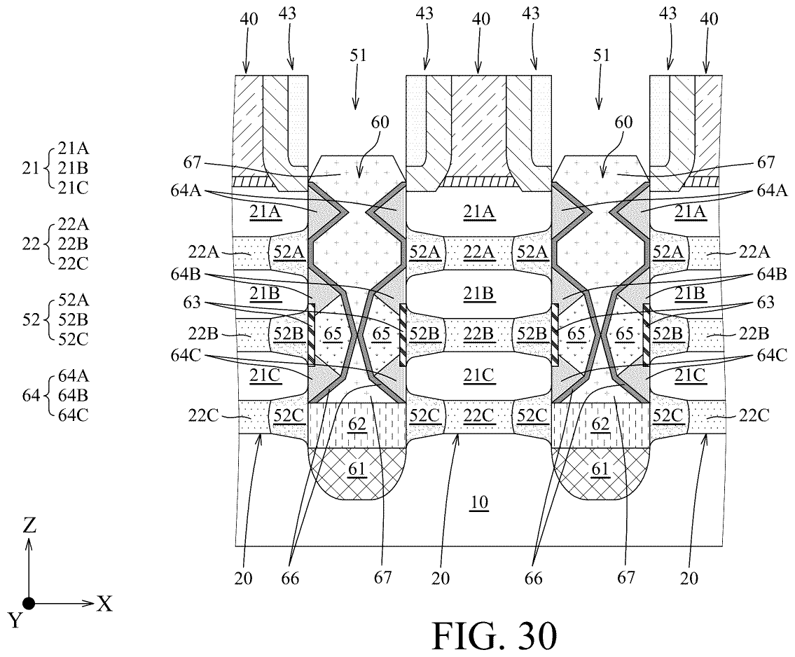

Referring to FIG. 30, different from the example illustrated in FIG. 16, in step 105, at the level where the inner spacers 52B are located, the epitaxial layer 67 with high Ge content is grown vertically from the bridging epitaxial feature (i.e., the epitaxial layers 65, 66 and the growth promotion elements 63).

Please note that the intermediate structure of FIG. 30 is also subjected to step 106 and 107 as described with reference to FIGS. 17 to 19, so as to achieve the resultant semiconductor structure shown in FIG. 31.

FIG. 32 is a schematic view of another semiconductor structure similar to that of FIG. 31, further illustrating the vertically grown epitaxial feature, i.e., the epitaxial layer 67. Please note that the growth promotion elements 63 are not shown in FIG. 32. As shown in FIGS. 31 and 32, the vertically grown epitaxial feature is formed in a mainly bottom-up approach (see the arrows in FIG. 32), and the epitaxial layer 67 containing the silicon germanium is grown from a relatively low level relative to the substrate 10, which is in contrast with those shown in FIGS. 19 and 20. Such vertically grown epitaxial features of FIGS. 31, 32 have a bottom-up growth portion above the bridging epitaxial feature, and a top-down growth portion beneath the bridging epitaxial feature, in which a first volume of the bottom-up growth portion is greater than a second volume of the top-down growth portion. It is noted that, the bottom-up growth portion, which has having a high Ge content (approximately greater than 30 atomic percentage as aforementioned) and a relatively large first volume (in comparison with the vertically grown epitaxial features shown in FIGS. 19 and 20, where the first volume of the bottom-up growth portion is smaller than the second volume of the top-down growth portion), may have a relatively small contact resistance with a metal contact (not shown, which is electrically in contact with the source/drain portion 60).

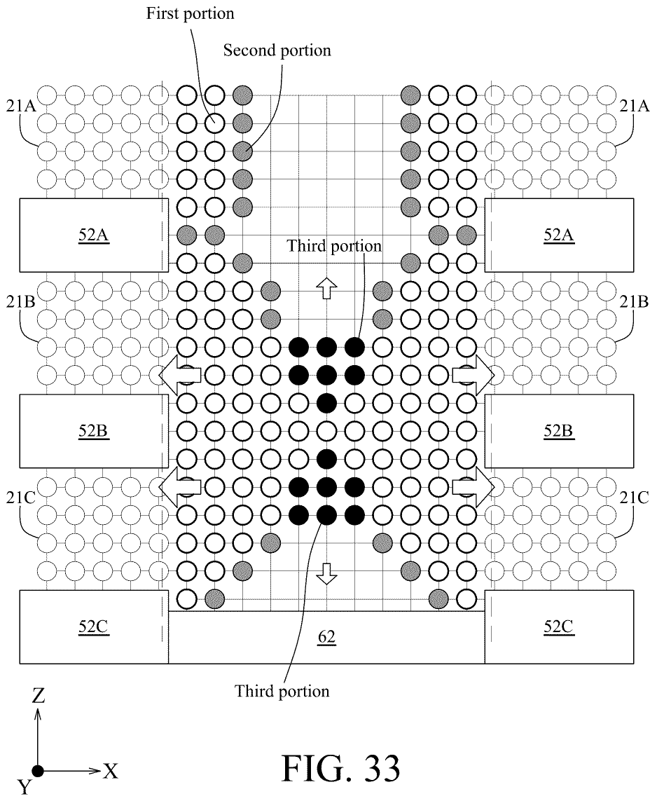

FIG. 33 is a schematic diagram similar to FIG. 22, except that the epitaxial layers 65 merge and bridge at the level of the predetermined inner spacers 52B. In some embodiments, the epitaxial layers 65 and the growth promotion elements 63 may serve as the bridging epitaxial feature (i.e., some of the first portions shown in FIG. 33), while both the epitaxial layers 66, 67 (i.e., the third portions) serve as the vertically grown epitaxial feature and are grown from the epitaxial layers 65 in the vertical direction (Z). The epitaxial layers 66, 67 cooperatively generate a compressive stress to the channel features 21A, 21B, 21C (the arrows indicates direction of the compressive stress).

In accordance with some embodiments, the epitaxial bridging features with epitaxial layers merge at the level of predetermined ones of the inner spacers 52 (52A, 52B, or 52C) may be achieved with or without formation of the growth promotion elements 63 as described in step 102 (though formation of the bottom epitaxial layer 61 and the FBI feature 62 in step 102 remains). In such case, in forming the nanosheet material stack as discussed in step 101, one of the second nanosheet layers, which is to be formed into ones of the sacrificial features 22 that are in positions corresponding to the predetermined ones of the inner spacers 52, may be formed with a smaller thickness (measured along the vertical direction (Z)). As such, the ones of the sacrificial features 22, and thus the predetermined ones of the inner spacers 52 may have a reduced thickness. As the predetermined ones of the inner spacers 52 that are to be formed with the epitaxial layers 65 have a reduced thickness, corresponding ones of the epitaxial regions 64 (that are adjacent to the predetermined ones of the inner spacers 52) may have a smaller spaced apart distance in the vertical direction (Z), and thus in the epitaxial growing process of the epitaxial layers 65, silicon germanium grown between the corresponding epitaxial regions 64 may take a shorter time period to merge (in comparison with the case that the thickness of the predetermined ones of the inner spacers 52 is not reduced), and beneficially resulting in a systematical formation of the epitaxial layers 65 on the predetermined ones of the inner spacers 52. In such case, formation of the growth promotion elements 63 may be omitted, and the bridging epitaxial feature may still be achieved.

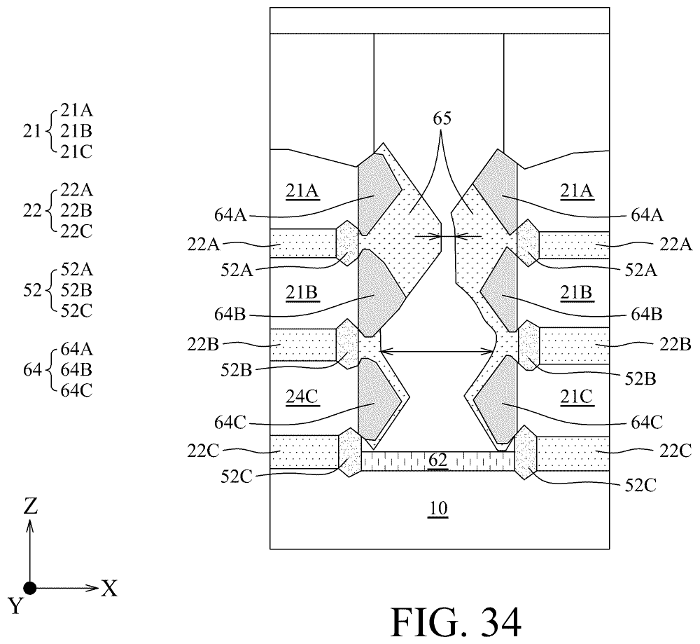

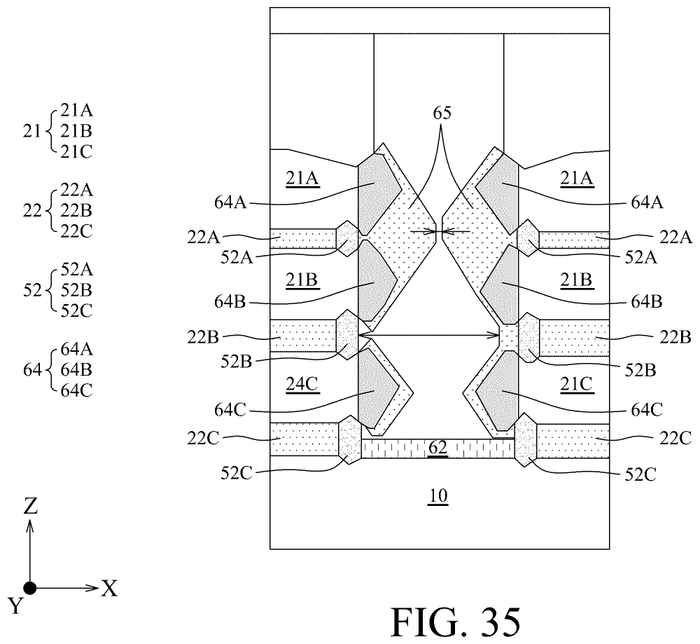

FIGS. 34 and 35 are schematic views of semiconductor structures obtained after kinetic atomistic simulation, illustrating the effect of reducing thickness of the sacrificial features 22 in accordance with some embodiments. As shown in FIG. 34, the sacrificial features 22A are formed to have a thickness that is smaller than a reference thickness of the sacrificial features 22B, 22C. After a certain period of time, the epitaxial layers 65 are formed at the predetermined inner spacers 52A with a relatively smaller spaced-apart distance between the epitaxial layers 65 denoted by the shorter arrow, while a relatively larger spaced-apart distance between the inner spacers 52B is denoted by the longer arrow. As shown in FIG. 35, the sacrificial features 22A are formed to have a thickness that is much smaller than the reference thickness of the sacrificial features 22B, 22C (in other words, the reference thickness of the sacrificial features 22B, 22C shown in FIGS. 34 and 35 are the same, but a thickness of the sacrificial features 22A shown in FIG. 35 is smaller than a thickness of the sacrificial features 22A shown in FIG. 34). After the same period of time for forming the epitaxial layers 65 (i.e., same as that of the epitaxial layers 65 shown in FIG. 34), the epitaxial layers 65 are formed at the predetermined inner spacers 52A with a relatively smaller spaced-apart distance denoted by the shorter arrow, while a relatively larger spaced-apart distance between the inner spacers 52B is denoted by the longer arrow. The structures shown in FIGS. 34 and 35 are similar to the structure shown in FIG. 14 in a manner that the epitaxial layers 65 formed on the predetermined inner spacers 52A are closely spaced apart from each other, and that the inner spacers 52B are widely spaced apart from each other; however, the structures shown in FIGS. 34 and 35 are different from the structure shown in FIG. 14 in that the growth promotion elements 63 are omitted in the structures shown in FIGS. 34 and 35, and the different ones of the inner spacers 52 (and corresponding ones of the sacrificial features 22) of the structures shown in FIGS. 34 and 35 are formed with different thickness. In accordance with some embodiments, the epitaxial layers 65 merge and serve as the bridging epitaxial feature, and the epitaxial layers 66, 67 formed thereon serve as the vertically grown epitaxial feature. In accordance with some other embodiments, epitaxial layers 65 do not merge, and epitaxial layers 66 merge at the level of the predetermined ones of the inner spacers 52, such epitaxial layers 65, 66 cooperatively serve as the bridging epitaxial feature, and the epitaxial layer 67 formed on the epitaxial layers 66 serve as the vertically grown epitaxial feature. In certain cases, without reducing thickness of the predetermined inner spacers 52, the epitaxial layers 65 are randomly grown at different inner spacers, resulting in random merging of the epitaxial layers 65, and thus the bridging epitaxial feature of the present disclosure cannot be obtained.

It is noted that, the predetermined inner spacers 52A shown in FIG. 35 are formed with a thickness smaller than the thickness of the predetermined inner spacers 52A shown in FIG. 34, and the spaced-apart distance between the epitaxial layers 65 at the level of the predetermined inner spacers 52A shown in FIG. 35 is smaller than the spaced-apart distance between the epitaxial layers 65 at the level of the predetermined inner spacers 52A shown in FIG. 34. These results suggest that, reduction of the thickness of the predetermined ones of the inner spacers (e.g. 52A), which can be achieved by reducing the thickness of the corresponding ones of the sacrificial features (e.g. 22A) (which are formed from a corresponding one of the second nanosheet layers during formation of the nanosheet stack), is effective in facilitating formation of the epitaxial layers 65 at the predetermined ones of the inner spacers (e.g. 52A). In accordance with the present disclosure, both surface treatment of the predetermined ones of the inner spacers 52 by forming the growth promotion elements 63, and reduction of thickness of the predetermined ones of the inner spacers 52, may be adopted singly or in combination, so that the epitaxial layers 65 can be formed at the predetermined ones of the inner spacers 52, thereby obtaining the bridging epitaxial feature, and thus the vertically grown epitaxial feature.

In the above discussion, the epitaxial layers 65 are formed only at the predetermined ones of the inner spacers 52 that are located at the same level, such that merging and bridging of the epitaxial layers occur at only one level where the predetermined ones of the inner spacers 52 are located, but not at other levels where other ones of the inner spacers 52 are located. The description in the following paragraphs compare and contrast different samples of semiconductor structures including the epitaxial layers 65, if any, which are formed in different manners.

In a semiconductor structure of a reference sample, none of the epitaxial layers 65 is formed. Stress levels of the channel features of the semiconductor structure are measured to obtain an average stress level that serves as a reference average stress level. In the reference sample, the stress levels across the channel features are inconsistent and vary (e.g., one of the channel features has a stress level of a negative value (meaning the channel feature is compressively stressed), and other ones of the channel features have a stress level of a positive value (meaning the channel features are tensily stressed)), and the reference average stress level is close to zero (a positive value), indicating that, the channel features of the reference sample, on average, is tensily stressed. A DC drive current level (I_{drive}) of the semiconductor structure is also measured to serve as a reference drive current level.

In a semiconductor structure of a sample (i), the epitaxial layers 65 are formed at different levels (e.g., at levels of both the inner spacers 52A and 52B), such that the epitaxial layers 65 and the epitaxial regions 64 on each of the sides of the source/drain recess 51 merge together (in other words, the sample (i) may have two bridging epitaxial features at levels of both the inner spacers 52A and 52B). It is noted that, any subsequent epitaxial layers, for example, L1 (the epitaxial layers 66), L2 (the epitaxial layers 67) formed subsequently, mostly exhibit a lateral growth, i.e., along the longitudinal direction (X). The stress levels across the channel features, average stress level and the drive current level of the semiconductor structure are found to be similar to the results of the reference sample.

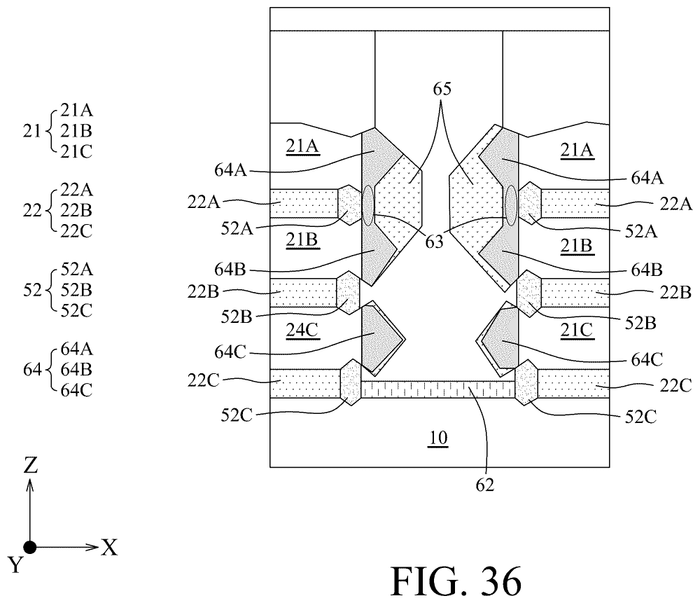

In a semiconductor structure of a sample (ii), the epitaxial layers 65 are formed at only one level. FIG. 36 is a schematic diagram showing the profile of the epitaxial regions 64 and the epitaxial layers 65 prior to forming the bridging epitaxial feature in accordance with some embodiments, in which the bridging epitaxial feature is to be formed at the level of the predetermined inner spacers 52A. In comparison with the reference sample, the stress levels across the channel features 21A, 21B, 21C in sample (ii) are more consistent and moderate (e.g., the stress level of each of the channel features 21A, 21B, 21C is a negative value (meaning that each of the channel features is compressively stressed)), and the average stress level of the semiconductor structure is a negative value, indicating that the channel features of the sample (ii) are compressively stressed. The drive current level of the semiconductor structure of sample (ii) is found to be about 10% to about 15% improved in comparison with the reference drive current level of the reference sample.

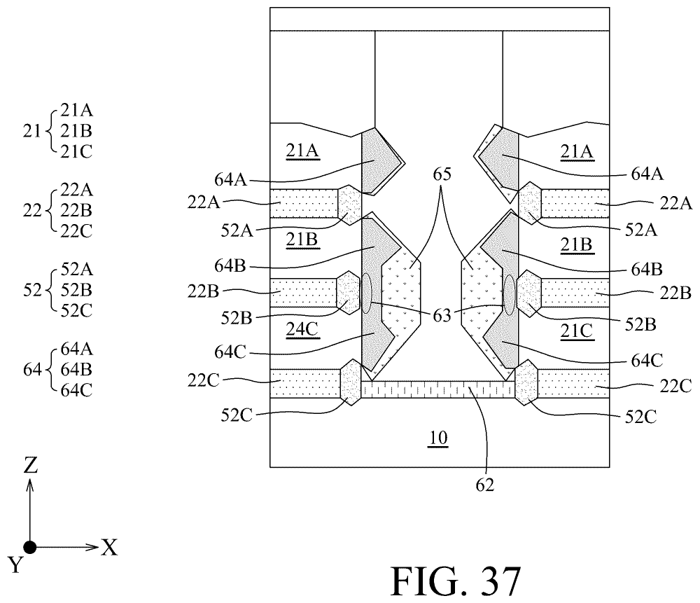

In a semiconductor structure of a sample (iii), the epitaxial layers 65 are also formed at only one level. FIG. 37 is a schematic diagram showing the profile of the epitaxial regions 64 and the epitaxial layers 65, prior to forming the bridging epitaxial feature in accordance with some embodiments, in which the bridging epitaxial feature is to be formed at the level of the predetermined inner spacers 52B. In comparison to the reference sample, the stress levels across the channel features 21A, 21B, 21C in sample (iii) are more consistent and moderate (e.g., the stress level of each of the channel features 21A, 21B, 21C is a negative value (meaning that each of the channel features is compressively stressed)), and the average stress level of the semiconductor structure is a negative value, indicating that the channel features of the sample (iv) are compressively stressed. The drive current level of the semiconductor structure of sample (iii) is found to be about 8% to about 12% improved in comparison with the reference drive current level of the reference sample.

The above results indicate that forming the epitaxial layers 65 at multiple levels may not promote growth of epitaxial layers having high Ge content in the vertical direction (Z), let alone the advantageous effects attributed thereto. In contrast, forming the epitaxial layers 65 at only one level promotes merging and bridging of the epitaxial layers 65 (or 66) at one single level (e.g., either at the predetermined inner spacers 52A, or 52B) so as to form the bridging epitaxial feature, and any subsequent epitaxial layers having high Ge content can be grown from the bridging epitaxial feature in the vertical direction (Z) effectively and serve as the vertically grown epitaxial feature. Such vertically grown epitaxial feature significantly produces a highly compressive stress in the channel features, so that performance of the semiconductor structure (e.g., the DC drive current) is significantly enhanced.

The embodiments of the present disclosure have the following advantageous features. The bridging epitaxial feature is formed to provide the growing base for the vertically grown epitaxial feature to grow therefrom in the vertical direction (Z), so as to provide a highly compressive stress to the channel features, thereby enhancing performance of the p-type semiconductor structure. Specifically, the bridging epitaxial feature is formed by growing the epitaxial layers 65 at the predetermined ones of the inner spacers 52 that are located at the same level, in a selective manner, so as to allow the subsequent epitaxial layers 66 to effectively and systematically merge at the level of the predetermined inner spacers 52.

In accordance with some embodiments of the present disclosure, a method for manufacturing a semiconductor structure includes: forming a patterned structure on a substrate, the patterned structure including: two first channel features spaced apart from each other by a source/drain recess; two second channel features disposed respectively beneath the two first channel features, and spaced apart from each other by the source/drain recess; two first sacrificial features, each of which is disposed between one of the two first channel features and a respective one of the two second channel features; two second sacrificial features disposed respectively beneath the two second channel features; two first inner spacers, each of which is disposed between the one of the two first channel features and the respective one of the two second channel features to separate a respective one of the two first sacrificial features from the source/drain recess; and two second inner spacers, each of which is disposed beneath one of the two second channel features to separate a respective one of the two second sacrificial features from the source/drain recess; forming a bridging epitaxial feature which interconnects two predetermined inner spacers that are the two first inner spacers or the two second inner spacers; and forming a vertically grown epitaxial feature from the bridging epitaxial feature in a vertical direction normal to the substrate.

In accordance with some embodiments of the present disclosure, prior to forming the bridging epitaxial feature, the method further including forming a bottom isolation at a bottom of the source/drain recess.

In accordance with some embodiments of the present disclosure, forming the bridging epitaxial feature includes: forming two growth promotion elements respectively on the two predetermined inner spacers; and forming two first epitaxial layers by introducing precursor molecules for forming the two first epitaxial layers to permit some of the precursor molecules to be adsorbed on the two growth promotion elements, the two first epitaxial layers being respectively formed on the two growth promotion elements, a germanium content of each of the two first epitaxial layers being less than a germanium content of the vertically grown epitaxial feature.

In accordance with some embodiments of the present disclosure, after forming the two growth promotion elements and before forming the two first epitaxial layers, the method further including forming epitaxial regions respectively from the two first channel features and the two second channel features, the epitaxial regions being free of germanium.

In accordance with some embodiments of the present disclosure, the two first epitaxial layers are formed to be merged together.

In accordance with some embodiments of the present disclosure, forming the bridging epitaxial feature further includes forming two second epitaxial layers respectively from the two first epitaxial layers, the two second epitaxial layers being formed to be merged together, a germanium content of each of the two second epitaxial layers being greater than the germanium content of each of the two first epitaxial layers, and less than the germanium content of the vertically grown epitaxial feature.

In accordance with some embodiments of the present disclosure, the two growth promotion elements are formed by performing a directional implantation process to deposit a growth promotion material on the two predetermined inner spacers.

In accordance with some embodiments of the present disclosure, the directional implantation process is performed with an energy level that is less than 5 kV.

In accordance with some embodiments of the present disclosure, each of the two growth promotion elements is made of a germanium-including material.

In accordance with some embodiments of the present disclosure, each of the two growth promotion elements has a thickness ranging from 0.2 nm to 1.0 nm.

In accordance with some embodiments of the present disclosure, a thickness of each of the two first sacrificial features is different from a thickness of each of the two second sacrificial features.

In accordance with some embodiments of the present disclosure, a method for manufacturing a semiconductor structure includes: forming a patterned structure on a substrate, the patterned structure including: two first channel features spaced apart from each other by a source/drain recess; two second channel features disposed respectively beneath the two first channel features, and spaced apart from each other by the source/drain recess; two first sacrificial features, each of which is disposed between one of the two first channel features and a respective one of the two second channel features; two second sacrificial features disposed respectively beneath the two second channel features; two first inner spacers, each of which is disposed between the one of the two first channel features and the respective one of the two second channel features to separate a respective one of the two first sacrificial features from the source/drain recess; and two second inner spacers, each of which is disposed beneath one of the two second channel features to separate a respective one of the two second sacrificial features from the source/drain recess; forming a bottom isolation at a bottom of the source/drain recess, the two first channel features, two second channel features, the two first inner spacers and the two second inner spacers being exposed from the bottom isolation; and forming a bridging epitaxial feature which interconnects two predetermined inner spacers which are the two first inner spacers or the two second inner spacers, the bridging epitaxial feature being formed only at a level of the two predetermined inner spacers.

In accordance with some embodiments of the present disclosure, the two predetermined inner spacers are the two first inner spacers, and forming the bridging epitaxial feature includes: forming a first blocking layer on the bottom isolation, the two first inner spacers being exposed from the first blocking layer; performing an implantation process to deposit a growth promotion material, a portion of which is formed into two growth promotion elements that are respectively located on the two first inner spacers; after the implantation process, forming a second blocking layer on the first blocking layer to protect the two growth promotion elements; performing a cleaning process to remove another portion of the growth promotion material which is exposed from the second blocking layer; after the cleaning process, removing the first blocking layer and the second blocking layer; and forming two first epitaxial layers by introducing precursor molecules for forming the two first epitaxial layers to permit some of the precursor molecules to be adsorbed on the two growth promotion elements, the two first epitaxial layers being respectively formed on the two growth promotion elements, a germanium content of each of the two first epitaxial layers being less than a germanium content of the vertically grown epitaxial feature.

In accordance with some embodiments of the present disclosure, the two predetermined inner spacers are the two second inner spacers, and forming the bridging epitaxial feature includes: performing an implantation process to deposit a growth promotion material, a portion of which is formed into two growth promotion elements that are respectively located on the two second inner spacers; after the implantation process, forming an upper blocking layer in the source/drain recess to protect the two growth promotion elements; performing a cleaning process to remove another portion of the growth promotion material which is exposed from the upper blocking layer; after the cleaning process, performing a removing process to remove the upper blocking layer; and forming two first epitaxial layers by introducing precursor molecules for forming the two first epitaxial layers to permit some of the precursor molecules to be adsorbed on the two growth promotion elements, the two first epitaxial layers being respectively formed on the two growth promotion elements, a germanium content of each of the two first epitaxial layers being less than a germanium content of the vertically grown epitaxial feature.

In accordance with some embodiments of the present disclosure, forming the bridging epitaxial feature further includes, prior to the implantation process, forming a lower blocking layer to cover the bottom isolation so that the two first channel features, two second channel features, the two first inner spacers and the two second inner spacers are exposed from the lower blocking layer; the upper blocking layer is formed on the lower blocking layer; and in the removing process, the lower blocking layer is removed with the upper blocking layer.

In accordance with some embodiments of the present disclosure, the method further including forming a vertically grown epitaxial feature from the bridging epitaxial feature in a vertical direction normal to the substrate, the vertically grown epitaxial feature having a bottom-up growth portion above the bridging epitaxial feature, and a top-down growth portion beneath the bridging epitaxial feature.

In accordance with some embodiments of the present disclosure, a volume of the bottom-up growth portion is different from a volume of the top-down growth portion.

In accordance with some embodiments of the present disclosure, forming the bridging epitaxial feature includes performing a surface treatment on the two predetermined inner spacers such that the bridging epitaxial feature is selectively formed at the two predetermined inner spacers.

In accordance with some embodiments of the present disclosure, a semiconductor structure includes: two first channel features, two second channel features, two active gates, two first inner spacers, two second inner spacers, and a source/drain portion. The two first channel features are spaced apart from each other by the source/drain portion. The two second channel features are disposed respectively beneath the two first channel features, and spaced apart from each other by the source/drain portion. Each of the two active gates is disposed to surround one of the two first channel features and a respective one of the two second channel features. Each of the two first inner spacers is disposed between the one of the two first channel features and the respective one of the two second channel features to separate a respective one of the two active gates from the source/drain portion. Each of the two second inner spacers is disposed beneath one of the two second channel features to separate a respective one of the two active gates from the source/drain portion. The source/drain portion includes a bridging epitaxial feature and a vertically grown epitaxial feature. The bridging epitaxial feature interconnects two predetermined inner spacers that are the two first inner spacers or the two second inner spacers. The vertically grown epitaxial feature is formed on the bridging epitaxial feature, and has a germanium content that is greater than a germanium content of the bridging epitaxial feature.

In accordance with some embodiments of the present disclosure, the vertically grown epitaxial feature has a bottom-up growth portion above the bridging epitaxial feature, and a top-down growth portion beneath the bridging epitaxial feature. A volume of the bottom-up growth portion is different from a volume of the top-down growth portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a patterned structure on a substrate, the patterned structure including:
two first channel features spaced apart from each other by a source/drain recess;
two second channel features disposed respectively beneath the two first channel features, and spaced apart from each other by the source/drain recess;
two first sacrificial features, each of which is disposed between one of the two first channel features and a respective one of the two second channel features;
two second sacrificial features disposed respectively beneath the two second channel features;
two first inner spacers, each of which is disposed between the one of the two first channel features and the respective one of the two second channel features to separate a respective one of the two first sacrificial features from the source/drain recess; and
two second inner spacers, each of which is disposed beneath one of the two second channel features to separate a respective one of the two second sacrificial features from the source/drain recess;
forming a bridging epitaxial feature which interconnects two predetermined inner spacers that are the two first inner spacers or the two second inner spacers; and
forming a vertically grown epitaxial feature from the bridging epitaxial feature in a vertical direction normal to the substrate.

2. The method according to claim 1, prior to forming the bridging epitaxial feature, further comprising:
forming a bottom isolation at a bottom of the source/drain recess.

3. The method according to claim 1, wherein forming the bridging epitaxial feature includes:
forming two growth promotion elements respectively on the two predetermined inner spacers; and
forming two first epitaxial layers by introducing precursor molecules for forming the two first epitaxial layers to permit some of the precursor molecules to be adsorbed on the two growth promotion elements, the two first epitaxial layers being respectively formed on the two growth promotion elements, a germanium content of each of the two first epitaxial layers being less than a germanium content of the vertically grown epitaxial feature.

4. The method according to claim 3, after forming the two growth promotion elements and before forming the two first epitaxial layers, further comprising:
forming epitaxial regions respectively from the two first channel features and the two second channel features, the epitaxial regions being free of germanium.

5. The method according to claim 3, wherein the two first epitaxial layers are formed to be merged together.

6. The method according to claim 3, wherein forming the bridging epitaxial feature further includes:
forming two second epitaxial layers respectively from the two first epitaxial layers, the two second epitaxial layers being formed to be merged together, a germanium content of each of the two second epitaxial layers being greater than the germanium content of each of the two first epitaxial layers, and less than the germanium content of the vertically grown epitaxial feature.

7. The method according to claim 3, wherein the two growth promotion elements are formed by performing a directional implantation process to deposit a growth promotion material on the two predetermined inner spacers.

8. The method according to claim 7, wherein the directional implantation process is performed with an energy level that is less than 5 kV.

9. The method according to claim 3, wherein each of the two growth promotion elements is made of a germanium-including material.

10. The method according to claim 3, wherein each of the two growth promotion elements has a thickness ranging from 0.2 nm to 1.0 nm.

11. The method according to claim 1, wherein a thickness of each of the two first sacrificial features is different from a thickness of each of the two second sacrificial features.

12. A method for manufacturing a semiconductor structure, comprising:
forming a patterned structure on a substrate, the patterned structure including:
two first channel features spaced apart from each other by a source/drain recess;
two second channel features disposed respectively beneath the two first channel features, and spaced apart from each other by the source/drain recess;
two first sacrificial features, each of which is disposed between one of the two first channel features and a respective one of the two second channel features;
two second sacrificial features disposed respectively beneath the two second channel features;
two first inner spacers, each of which is disposed between the one of the two first channel features and the respective one of the two second channel features to separate a respective one of the two first sacrificial features from the source/drain recess; and
two second inner spacers, each of which is disposed beneath one of the two second channel features to separate a respective one of the two second sacrificial features from the source/drain recess;
forming a bottom isolation at a bottom of the source/drain recess, the two first channel features, two second channel features, the two first inner spacers and the two second inner spacers being exposed from the bottom isolation; and
forming a bridging epitaxial feature which interconnects two predetermined inner spacers which are the two first inner spacers or the two second inner spacers, the bridging epitaxial feature being formed only at a level of the two predetermined inner spacers.

13. The method according to claim 12, wherein the two predetermined inner spacers are the two first inner spacers, and forming the bridging epitaxial feature includes:
forming a first blocking layer on the bottom isolation, the two first inner spacers being exposed from the first blocking layer;
performing an implantation process to deposit a growth promotion material, a portion of which is formed into two growth promotion elements that are respectively located on the two first inner spacers;
after the implantation process, forming a second blocking layer on the first blocking layer to protect the two growth promotion elements;
performing a cleaning process to remove another portion of the growth promotion material which is exposed from the second blocking layer;
after the cleaning process, removing the first blocking layer and the second blocking layer; and
forming two first epitaxial layers by introducing precursor molecules for forming the two first epitaxial layers to permit some of the precursor molecules to be adsorbed on the two growth promotion elements, the two first epitaxial layers being respectively formed on the two growth promotion elements, a germanium content of each of the two first epitaxial layers being less than a germanium content of the vertically grown epitaxial feature.

14. The method according to claim 12, wherein the two predetermined inner spacers are the two second inner spacers, and forming the bridging epitaxial feature includes:
performing an implantation process to deposit a growth promotion material, a portion of which is formed into two growth promotion elements that are respectively located on the two second inner spacers;
after the implantation process, forming an upper blocking layer in the source/drain recess to protect the two growth promotion elements;
performing a cleaning process to remove another portion of the growth promotion material which is exposed from the upper blocking layer;
after the cleaning process, performing a removing process to remove the upper blocking layer; and
forming two first epitaxial layers by introducing precursor molecules for forming the two first epitaxial layers to permit some of the precursor molecules to be adsorbed on the two growth promotion elements, the two first epitaxial layers being respectively formed on the two growth promotion elements, a germanium content of each of the two first epitaxial layers being less than a germanium content of the vertically grown epitaxial feature.

15. The method according to claim 14, wherein:
forming the bridging epitaxial feature further includes, prior to the implantation process, forming a lower blocking layer to cover the bottom isolation so that the two first channel features, two second channel features, the two first inner spacers and the two second inner spacers are exposed from the lower blocking layer;
the upper blocking layer is formed on the lower blocking layer; and
in the removing process, the lower blocking layer is removed with the upper blocking layer.

16. The method according to claim 12, further comprising:
forming a vertically grown epitaxial feature from the bridging epitaxial feature in a vertical direction normal to the substrate, the vertically grown epitaxial feature having a bottom-up growth portion above the bridging epitaxial feature, and a top-down growth portion beneath the bridging epitaxial feature.

17. The method according to claim 16, wherein a volume of the bottom-up growth portion is different from a volume of the top-down growth portion.

18. The method according to claim 12, wherein forming the bridging epitaxial feature includes performing a surface treatment on the two predetermined inner spacers such that the bridging epitaxial feature is selectively formed at the two predetermined inner spacers.

19. A semiconductor structure, comprising:
two first channel features spaced apart from each other by a source/drain portion;
two second channel features disposed respectively beneath the two first channel features, and spaced apart from each other by the source/drain portion;
two active gates each of which is disposed to surround one of the two first channel features and a respective one of the two second channel features;
two first inner spacers, each of which is disposed between the one of the two first channel features and the respective one of the two second channel features to separate a respective one of the two active gates from the source/drain portion; and
two second inner spacers, each of which is disposed beneath one of the two second channel features to separate a respective one of the two active gates from the source/drain portion,
the source/drain portion including
a bridging epitaxial feature which interconnects two predetermined inner spacers that are the two first inner spacers or the two second inner spacers, and
a vertically grown epitaxial feature formed on the bridging epitaxial feature, and having a germanium content that is greater than a germanium content of the bridging epitaxial feature.

20. The method according to claim 19, wherein the vertically grown epitaxial feature has a bottom-up growth portion above the bridging epitaxial feature, and a top-down growth portion beneath the bridging epitaxial feature, a volume of the bottom-up growth portion being different from a volume of the top-down growth portion.
